(19) United States
(12) Patent Application Publication
(10) Pub. No.: US 2025/0098481 A1
(43) Pub. Date: Mar. 20, 2025

(54) DISPLAY DEVICE

(71) Applicant: LG ELECTRONICS INC., Seoul (KR)

(72) Inventors: Youngkeun CHOI, Seoul (KR); Kwanghun YUN, Seoul (KR); Sungwoo LEE, Seoul (KR)

(73) Assignee: LG ELECTRONICS INC., Seoul (KR)

(21) Appl. No.: 18/773,254

(22) Filed: Jul. 15, 2024

(30) Foreign Application Priority Data
Sep. 14, 2023 (KR) 10-2023-0122139

(51) Int. Cl. H10K 59/80

(52) U.S. Cl. CPC H10K 59/872

(57) ABSTRACT

A display device is disclosed. The display device includes: a display panel; a material complexed panel positioned at a rear of the display panel; and a side frame positioned between the display panel and the material complexed panel, fixed to the material complexed panel, and to which the display panel is coupled, wherein the material complexed panel includes: a front skin that defines a front surface of the material complexed panel; a rear skin that defines a rear surface of the material complexed panel, the rear skin facing the front skin; and a core positioned between the front skin and the rear skin, the core including fibers.

### CROSS-REFERENCE TO RELATED APPLICATION(S)

Pursuant to 35 U.S.C. § 119, this application claims the benefit of earlier filing date and right of priority to Korean Application No(s). 10-2023-0122139, filed on Sep. 14, 2023, the contents of which are all incorporated by reference herein in its entirety.

### BACKGROUND

### 1. Field

The present disclosure relates to a display device.

### 2. Description of the Related Art

With the development of information society, there has been a growing demand for various types of display devices. In order to meet such demand, various display devices, such as a liquid crystal display (LCD), a plasma display panel (PDP), an electro luminescent display (ELD), a vacuum fluorescent display (VFD), an organic light emitting diode (OLED), and the like, have been developed and used.

Among them, a display device using an organic light emitting diode (OLED) has excellent luminance and viewing angle characteristics compared to a liquid crystal display device, and requires no backlight unit, which is advantageous to achieve an ultra-thin profile.

Recently, numerous research has been conducted to obtain the rigidity and structural stability of an ultra-thin large screen display device.

### SUMMARY

It is an objective of the present disclosure to solve the above and other problems.

It is another objective of the present disclosure to achieve structural rigidity of an ultra-thin large screen display device.

It is yet another objective of the present disclosure to achieve structural stability of a display device.

It is yet another objective of the present disclosure to improve the flatness of a frame of a display device.

It is yet another objective of the present disclosure to prevent a short circuit or damage of a driver IC of a display panel.

According to an aspect of the subject matter described in this application, a display device includes: a display panel; a material complexed panel positioned at a rear of the display panel; and a side frame positioned between the display panel and the material complexed panel, fixed to the material complexed panel, and to which the display panel is coupled, wherein the material complexed panel includes: a front skin that defines a front surface of the material complexed panel; a rear skin that defines a rear surface of the material complexed panel, the rear skin facing the front skin; and a core positioned between the front skin and the rear skin, the core including fibers.

A display device according to the present disclosure has the following effects.

According to at least one of the embodiments of the present disclosure, it is possible to achieve structural rigidity of an ultra-thin large screen display device.

According to at least one of the embodiments of the present disclosure, it is possible to achieve structural stability of a display device.

According to at least one of the embodiments of the present disclosure, it is possible to improve the flatness of a frame of a display device.

According to at least one of the embodiments of the present disclosure, it is possible to prevent a short circuit or damage of a driver IC of a display panel.

Further scope of applicability of the present disclosure will become apparent from the following detailed description. It should be understood, however, that the configurations in the detailed description are given by way of illustration only, since various changes and modifications within the idea and scope of the present disclosure will be apparent to those skilled in the art.

### BRIEF DESCRIPTION OF THE DRAWINGS

FIGS. 1 to 39 illustrate examples of a display device according to embodiments of the present disclosure.

### DETAILED DESCRIPTION

Description will now be given in detail according to exemplary embodiments disclosed herein, with reference to the accompanying drawings. For the sake of brief description with reference to the drawings, the same or equivalent components may be denoted by the same reference numbers, and description thereof will not be repeated.

In the following description, a suffix such as “module” and “unit” may be used to refer to elements or components. Use of such a suffix herein is merely intended to facilitate description of the specification, and the suffix itself is not intended to give any special meaning or function.

In the present disclosure, that which is well known to one of ordinary skill in the relevant art has generally been omitted for the sake of brevity. The accompanying drawings are used to help easily understand the technical idea of the present disclosure and it should be understood that the idea of the present disclosure is not limited by the accompanying drawings. The idea of the present disclosure should be construed to extend to any alterations, equivalents, and substitutes besides the accompanying drawings.

It will be understood that although the terms “first”, “second”, etc. may be used herein to describe various elements, these elements should not be limited by these terms. These terms are only used to distinguish one element from another.

It will be understood that when a component is referred to as being “connected to” or “coupled to” another component, it may be directly connected to or coupled to another component, or intervening components may be present. In contrast, when a component is referred to as being “directly connected to” or “directly coupled to” another component, there are no intervening components present.

As used herein, a singular representation is intended to include a plural representation unless the context clearly indicates otherwise.

In the following description, when an embodiment is described with reference to a specific figure, reference numeral not shown in the specific figure may be mentioned, if necessary or desired. However, the reference numeral not shown in the specific figure may be mentioned only when the reference numeral is shown in other figures.

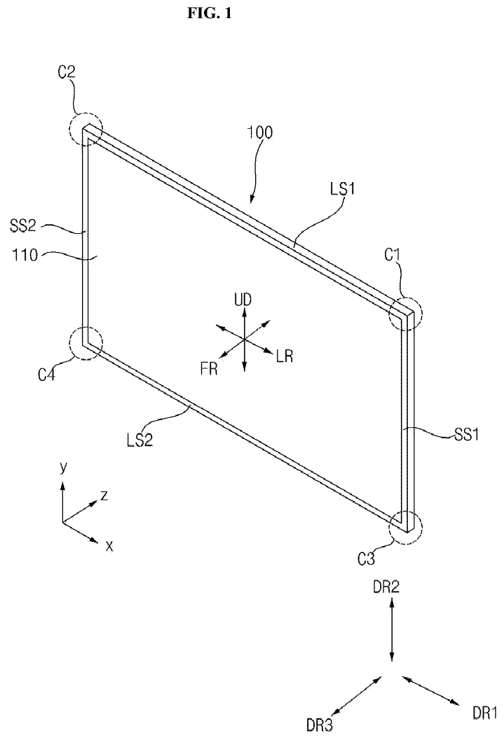

Referring to FIG. 1, a display device 100 may include a display panel 110. The display panel 110 may display an image.

The display device 100 may include a first long side LS1, a second long side LS2 opposite the first long side LS1, a first short side SS1 adjacent to the first long side LS1 and the second long side LS2, and a second short side SS2 opposite the first short side SS1.

For ease of explanation, it is illustrated and described that lengths of the first and second long sides LS1 and LS2 are greater than lengths of the first and second short sides SS1 and SS2, but the lengths of the first and second long sides LS1 and LS2 may be substantially equal to the lengths of the first and second short sides SS1 and SS2.

A direction parallel to the long sides LS1 and LS2 of the display device 100 may be referred to as a first direction DR1 or a left-and-right direction LR. A direction parallel to the short sides SS1 and SS2 of the display device 100 may be referred to as a second direction DR2 or an up-and-down direction UD.

A direction perpendicular to the long sides LS1 and LS2 and the short sides SS1 and SS2 of the display device 100 may be referred to as a third direction DR3 or a front-and-rear direction FR. Here, a direction in which the display panel 110 displays an image may be referred to as a front, and a direction opposite to the front may be referred to as a rear.

Hereinafter, a display panel using an organic light emitting diode (OLED) will be described as an example for the display panel 110, but the display panel 110 applicable to the present disclosure is not limited thereto.

The display panel 110 may define a front surface of the display device 100, and may display an image forward. The display panel 110 may include a plurality of pixels and output an image in accordance with color, brightness, and chroma of each pixel. The display panel 110 may be divided into an active area in which an image is displayed and a de-active area in which no image is displayed. The display panel 110 may generate light corresponding to red, green, or blue color according to a control signal.

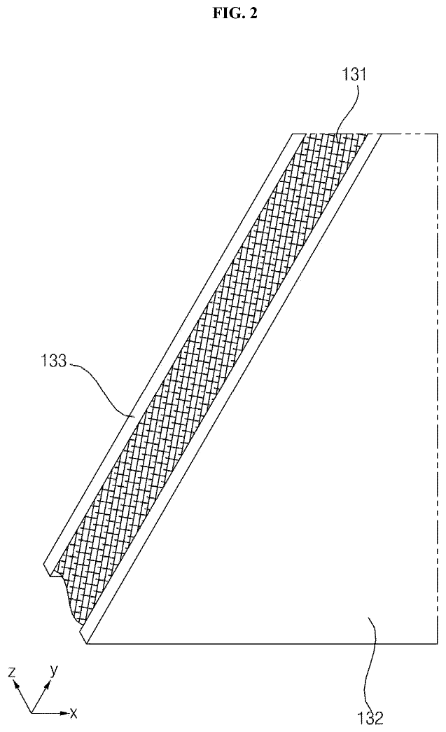

Referring to FIG. 2, a material complexed panel 130 may include a core 131, a front skin 132, and a rear skin 133. The core 131, the front skin 132, and the rear skin 133 may be coupled to each other. The material complexed panel 130 may be referred to as a fiber complexed panel 130, a fiber complexed plate 130, a material complexed plate 130, a middle frame 130, a rear cover 130, or a rear plate 130.

The front skin 132 may define a front surface of the material complexed panel 130. The rear skin 133 may define a rear surface of the material complexed panel 130. The front skin 132 and the rear skin 133 may include a metal material.

For example, the front skin 132 and the rear skin 133 may be a galvanized iron sheet. As another example, the front skin 132 and the rear skin 133 may include aluminum (Al).

For example, the thickness of the front skin 132 and the rear skin 133 may be 0.2 to 0.5 mm. As another example, the thickness of the front skin 132 and the rear skin 133 formed of a galvanized iron sheet may be 0.27 mm. As another example, the thickness of the front skin 132 and the rear skin 133 including aluminum (Al) may be 0.5 mm.

The front skin 132 and the rear skin 133 may be disposed opposite each other with respect to the core 131, which will be described below. The core 131 may be positioned between the front skin 132 and the rear skin 133. The core 131 may include fibers. The core 131 may be formed of a composite material. The core 131 may include a main fiber and a binder fiber. The binder fiber may be mixed with the main fiber.

The front skin 132 and/or the rear skin 133 may be coupled to the core 131 by hot-melt processing. A hot-melt sheet may be disposed between the front skin 132 and the core 131, and a hot-melt sheet may be disposed between the rear skin 133 and the core 131. The hot-melt sheet may be a film. For example, the hot-melt sheet may be a film made of EVA, acrylic, polyurethane, or the like having a thickness of 50 μm or more. After the core 131 is placed between the front skin 132 and the rear skin 133 by the hot-melt sheets, roll lamination may be performed at 190° C. for 1 minute or more.

Thus, it is possible to increase bending rigidity and/or torsional rigidity of the display device.

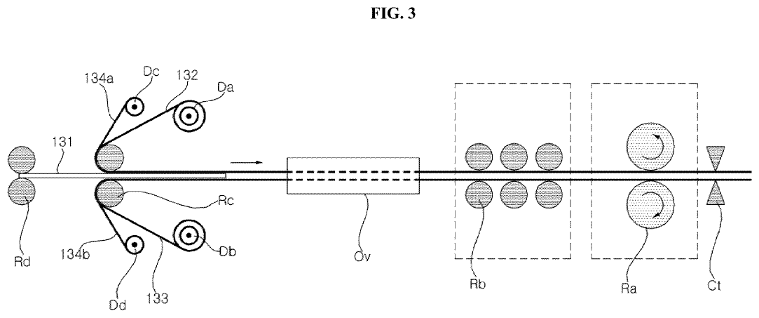

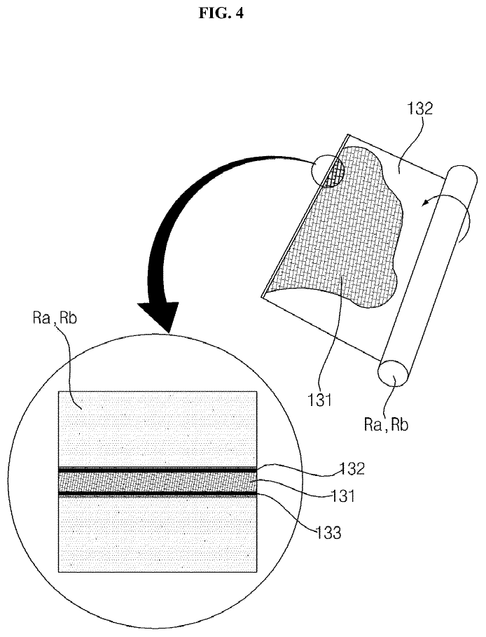

Referring to FIGS. 3 and 4, the material complexed panel 130 may be manufactured by a process of pressing the front skin 132 and the rear skin 133 onto the core 131 using a plurality of rollers. Such a process may be referred to as a Roll-to-Roll (R2R) process.

Referring to FIG. 3, as a pinch roller Ra serving as a drive motor rotates, the front skin 132 may be unwound from a front drum Da, the rear skin 133 may be unwound from a rear drum Db, and the core 131 may be moved by passing through a feeding roller Rd. In addition, a first adhesive 134a for coupling the front skin 132 to the core 131 may be unwound from a first drum Dc. Also, a second adhesive 134b for coupling the rear skin 133 to the core 131 may be unwound from a second drum Db. In this case, the front skin 132, the first adhesive 134a, the core 131, the second adhesive 134b, and the rear skin 133 are stacked in this order, and may be guided toward an oven Ov by a guide roller Rc. The adhesives 134a and 134b may be hot-melt sheets 134a and 134b.

As the first and second adhesives 134a and 134b are melted in the oven Ov, each of the front skin 132 and the rear skin 133 may be coupled to the core 131. For example, the melting point of the first and second adhesives 134a and 134b may be about 150° C., and the ambient temperature of the oven Ov may be about 200° C. For example, the peel-off force of the first and second adhesives 134a and 134b may be about 10 kgf or more.

The front skin 132, the core 131, and the rear skin 133 that have passed through the oven Ov may be guided to a press roller Rb by the rotation of the pinch roller Ra, so as to be pressed by the press roller Rb. Accordingly, the coupling force among the front skin 132, the core 131, and the rear skin 133 may be further increased. The front skin 132, the core 131, and the rear skin 133, which are coupled to each other, may pass through the pinch roller Ra, and then may be cut by a cutter Ct to be manufactured as a material complexed panel 130 of a predetermined size.

Referring to FIG. 4, the press roller Rb or the pinch roller Ra may be brought into contact with an outer surface of each of the front skin 132 and the rear skin 133. When the press roller Rb or the pinch roller Ra rotates, the material complexed panel 130 may be moved in a longitudinal direction of the core 131 (i.e., the left-and-right direction LR). Here, the front skin 132 and the rear skin 133 may be coupled to the core 131 sequentially from one end to the other end in the longitudinal direction of the core 131.

In addition, the front skin 132 and the rear skin 133 of the material complexed panel 130 may be formed flat. That is, as a rear surface of the rear skin 133, which defines a rear surface of the display device 100, is formed flat, it may facilitate an additional operation, such as painting the rear surface of the rear skin 133, attaching a sheet thereto, or the like, for an aesthetically pleasing appearance.

Meanwhile, in addition to the R2R process described above with reference to FIGS. 3 and 4, which is used for making the front skin 132 and the rear skin 133 flat, a process of sequentially stacking the front skin 132, the core 131, and the rear skin 133 followed by coupling the same may be used.

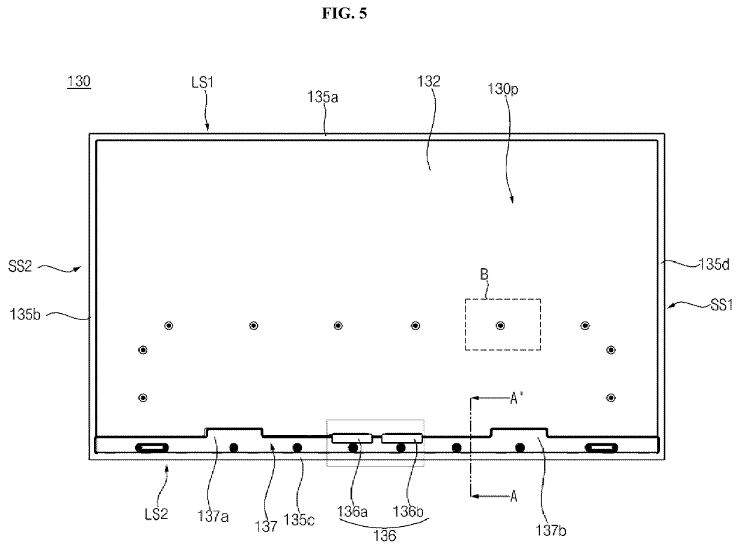

Referring to FIG. 5, the material complexed panel 130 may include a flat part 130P, a receiving part 137, and an outer part 135. The outer part 135 may be formed around the flat part 130P. A first outer part 135a may be formed along an upper side of the flat part 130P, a second outer part 135b may be formed along a left side of the flat part 130P, a third outer part 135c may be formed along a lower side of the flat part 130P, and a fourth outer part 135d may be formed along a right side of the flat part 130P. The outer part 135 may be formed as the flat part 130P is pressed. The outer part 135 may be lowered from the flat part 130P to thereby form a step. The flat part 130P may have a greater thickness than the outer part 135.

A cable hole 136 may be formed through the front skin 132 (see FIG. 2) and the rear skin 133 (see FIG. 2) of the receiving part 137. The cable hole 136 may be formed in the receiving part 137 while being adjacent to the lower side of the flat part 130P. The cable hole 136 may be provided in plurality. A first cable hole 136a and a second cable hole 136b may be positioned adjacent to each other.

The receiving part 137 may be formed between the flat part 130P and the third outer part 135c while being adjacent to the lower side of the flat part 130P. The receiving part 137 may be provided in plurality. A first receiving part 137a may be positioned between the first cable hole 136a and the second short side SS2. A second receiving part 137b may be positioned between the second cable hole 136b and the first short side SS1. The receiving part 137 may be formed as the flat part 130P is pressed. The receiving part 137 may be lowered from the flat part 130P and/or the outer part 135c to thereby form a step.

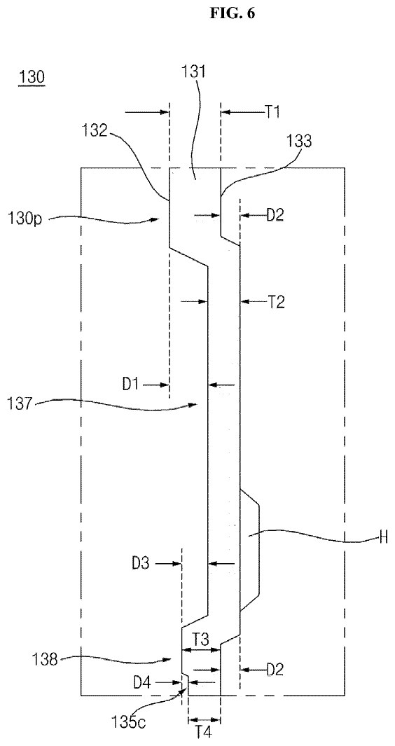

Referring to FIG. 6, the receiving part 137 may be formed as the flat part 130P is pressed. The front skin 132 of the receiving part 137 may form a step D1 descending from the front skin 132 of the flat part 130P. The rear skin 133 of the receiving part 137 may form a step D2 ascending from the rear skin 133 of the flat part 130P. Here, a height of the step D1 descending from the front skin 132 of the flat part 130P to the front skin 132 of the receiving part 137 may be greater than a height of the step D2 ascending from the rear skin 133 of the flat part 130P to the rear skin 133 of the receiving part 137. A thickness T1 of the flat part 130P may be greater than a thickness T2 of the receiving part 137.

As the core 131 of the material complexed panel 130 is pressed in a direction from the front skin 132 to the rear skin 133 of the flat part 130P, the core 131 may absorb an external force. The magnitude of the external force applied to the front skin 132 of the flat part 130P may be greater than the magnitude of the external force applied to the rear skin 133 of the flat part 130P. The core 131 of the material complexed panel 130 may absorb impact as well as achieve rigidity.

A thickness T4 of the third outer part 135c may be greater than the thickness T2 of the receiving part 137. A step D2 ascending from the rear skin 133 of the third outer part 135c to the rear skin 133 of the receiving part 137 may be formed. A height of the step D2 between the rear skin 133 of the third outer part 135c and the rear skin 133 of the receiving part 137 may be equal to the height of the step D2 between the rear skin 133 of the receiving part 137 and the rear skin 133 of the flat part 130P.

A protruding pad 138 may be formed by protruding from the front skin 132 of the third outer part 135c. The front skin 132 of the protruding pad 138 may form a step D4 descending to the front skin 132 of the third outer part 135c. A height of the step D4 formed by the third outer part 135c and the protruding pad 138 may be less than the height of the steps D1 and D2 formed by the flat part 130P and the receiving part 137. A thickness T3 of the protruding pad 138 may be greater than the thickness T4 of the third outer part 135c, may be less than the thickness T1 of the flat part 130P, and may be less than the thickness T2 of the receiving part 137.

A fastening groove H may protrude from the rear skin 133 of the receiving part 137. The fastening groove H may be recessed in the front skin 132 of the receiving part 137 and may protrude from the rear skin 133 of the receiving part 137. A central portion of the fastening groove H may be penetrated.

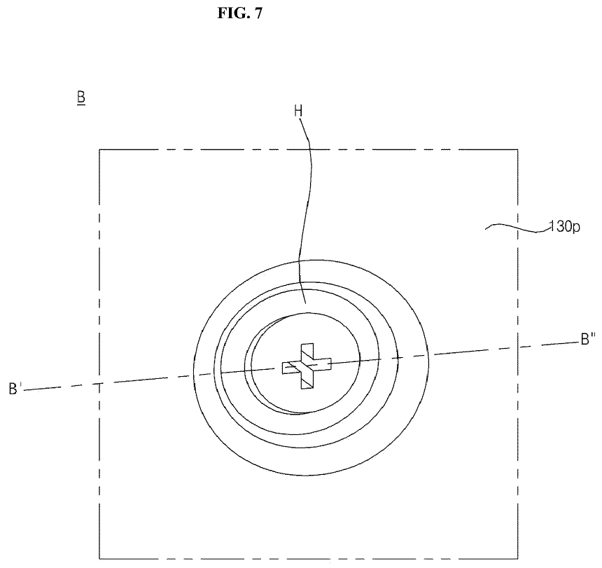

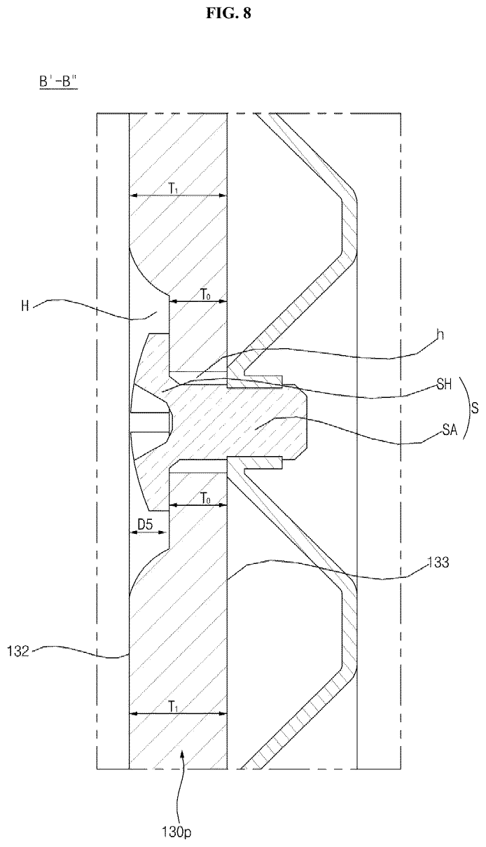

Referring to FIGS. 7 and 8, a fastening groove H may be formed in the flat part 130P. The fastening groove H may be formed as the flat part 130P is pressed. The front skin 132 of the fastening groove H may be formed by being recessed from the front skin 132 of the flat part 130P. The rear skin 133 of the flat part 130P and the rear skin 133 of the fastening groove H may form the same plane. A thickness T0 of the fastening groove H may be less than a thickness T1 of the flat part 130P.

The fastening groove H may be provided at its center with a fastening hole h. The fastening hole h may be formed by punching the fastening groove H. The fastening hole h may be formed through the front skin 132 and the rear skin 133 of the fastening groove H. A shaft SA of a fastening member S may have a length greater than the thickness T0 of the fastening groove H. The shaft SA of the fastening member S may be inserted into the fastening groove H and protrude to an outside of the rear skin 132 of the fastening groove H through the fastening hole h. A depth D5 of the fastening groove H may be greater than a thickness of a head SH. The head SH of the fastening member S may be hidden in the fastening groove H.

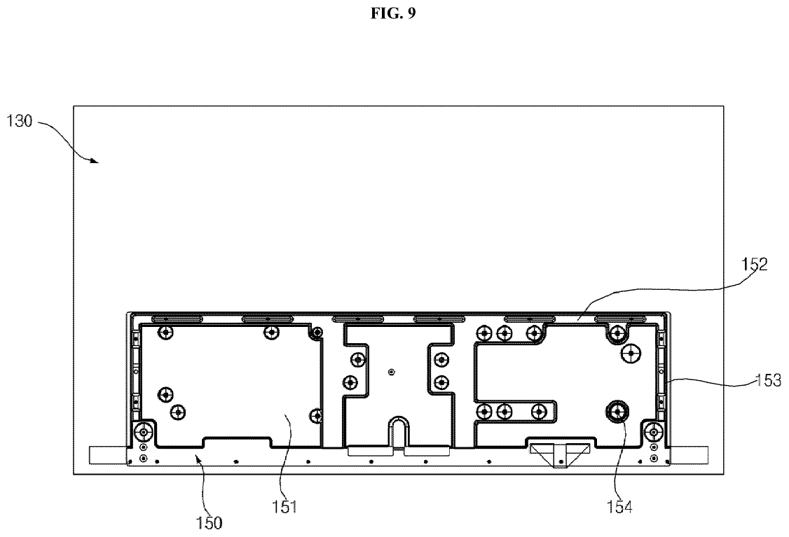

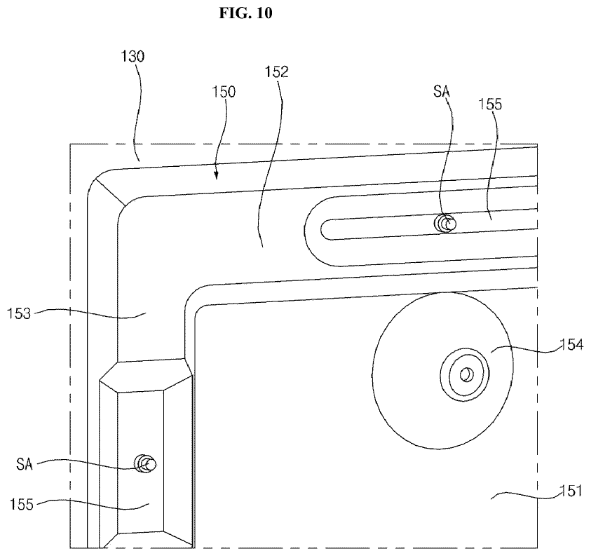

Referring to FIGS. 9 and 10 together with FIG. 8, a PCB plate 150 may be coupled to the rear of the material complexed panel 130. The PCB plate 150 may be fixed to the rear of the material complexed panel 130 by the fastening member S.

The PCB plate 150 may be formed by pressing a plate 151 including a metal. The PCB plate 150 may include a horizontal portion 152, a vertical portion 153, a dome portion 154, and a recessed portion 155. The horizontal portion 152 may protrude from the front to the rear of the PCB plate 151 and may be elongated in a left-and-right direction of the PCB plate 151. The vertical portion 153 may protrude from the front to the rear of the PCB plate 151 and may be elongated in an up-and-down direction of the PCB plate 150. The dome portion 154 may protrude from the front to the rear of the PCB plate 150. The recessed portion 155 may be recessed forward from the rear of the vertical portion 153 and/or the horizontal portion 152.

The shaft SA of the fastening member S may pass through the recessed portion 155 formed in the vertical portion 153 and/or the horizontal portion 152 to couple the material complexed panel 130 with the PCB plate 150. A depth of the recessed portion 155 may be greater than a protruding length of the shaft SA of the fastening member S protruding rearward through the material complexed panel 130.

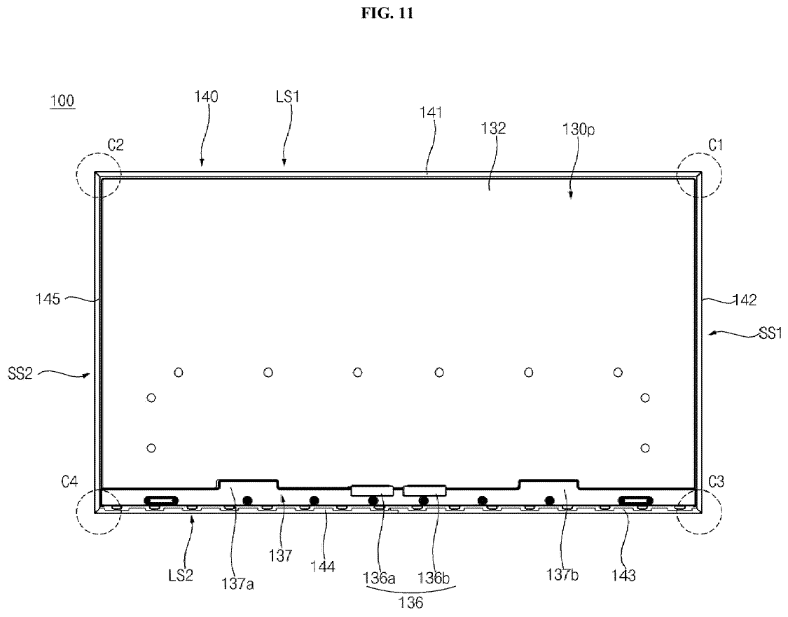

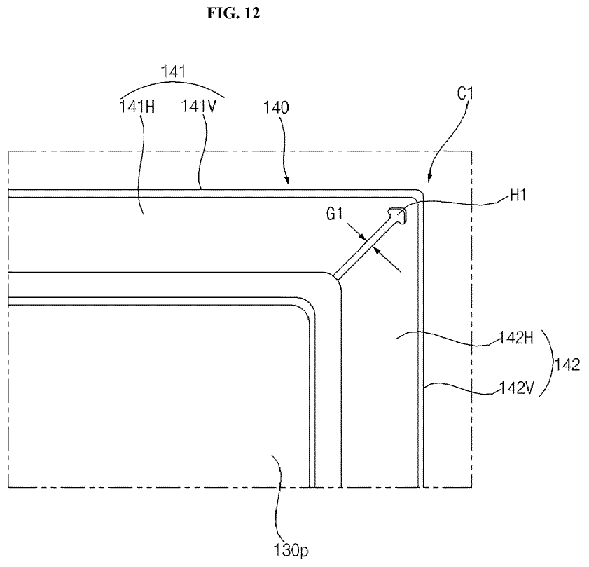

Referring to FIGS. 11 and 12, a side frame 140 may be coupled to the outer part 135 (see FIG. 5) while being adjacent to the flat part 130P. The side frame 140 may include a first part 141, a second part 142, a third part 143, a fourth part 144, and a fifth part 145. The second part 142 may be bent at a first corner C1 from the first part 141.

The first part 141 may include a horizontal portion 141H and a vertical portion 141V. The horizontal portion 141H of the first part 141 may be fixed on the first outer part 135a (see FIG. 5). The second part 142 may include a horizontal portion 142H and a vertical portion 142V. The horizontal portion 142H of the second part 142 may be fixed on the fourth outer part 135d (see FIG. 5).

A gap G1 may be formed between the horizontal portion 141H of the first part 141 and the horizontal portion 142H of the second part 142. The vertical portion 141V of the first part 141 and the vertical portion 142V of the second part 142 may be connected while being bent. A hole H1 connected to the gap G1 may be formed between the horizontal portions 141H and 142H while being adjacent to the vertical portions 141V and 142V. A size of the hole H1 or a diameter of the hole H1 may be greater than a width of the gap G1. The description of the first corner C1 of the side frame 140 is equally applicable to a second corner C2 of the side frame 140.

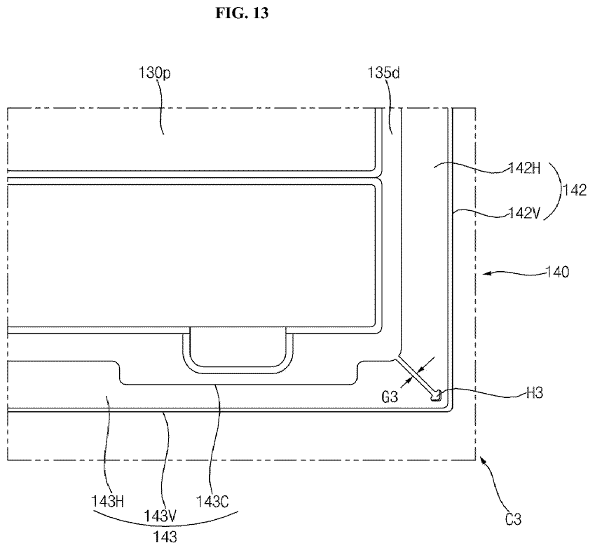

Referring to FIG. 11 and FIG. 13, the side frame 140 may be coupled to the outer part 135 (see FIG. 5) while being adjacent to the flat part 130P. The side frame 140 may include a first part 141, a second part 142, a third part 143, a fourth part 144, and a fifth part 145. The second part 142 may be bent at a third corner C3 from the third part 143.

The third part 143 may include a horizontal portion 143H and a vertical portion 143V. The horizontal portion 143H of the third part 143 may be fixed on the third outer part 135c (see FIG. 5). The second part 142 may include a horizontal portion 142H and a vertical portion 142V. The horizontal portion 142H of the second part 142 may be fixed on the fourth outer part 135d (see FIG. 5).

A gap G3 may be formed between the horizontal portion 143H of the third part 143 and the horizontal portion 142H of the second part 142. The vertical portion 143V of the third part 143 and the vertical portion 142V of the second part 142 may be connected while being bent. A hole H3 connected to the gap G3 may be formed between the horizontal portions 143H and 142H while being adjacent to the vertical portions 143V and 142V. A size of the hole H3 or a diameter of the hole H3 may be greater than a width of the gap G3. The description of the third corner C3 of the side frame 140 is equally applicable to a fourth corner C4 of the side frame 140.

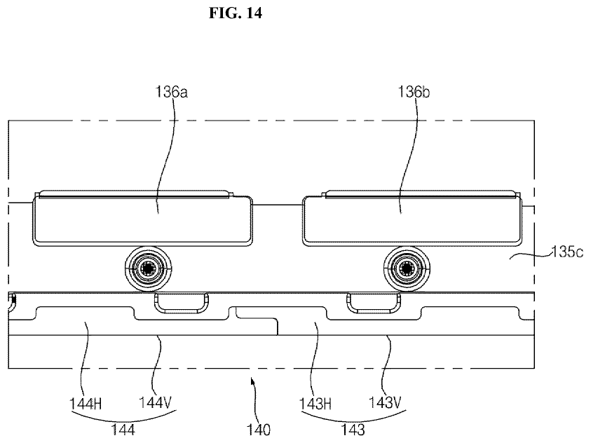

Referring to FIG. 11 and FIG. 14, the third part 143 and the fourth part 144 of the side frame 140 may be positioned or fixed on the third outer part 135c. An end of the third part 143 of the side frame 140 may be coupled to an end of the fourth part 144 of the side frame 140.

A horizontal portion 144H of the fourth part 144 may contact the horizontal portion 143H and the vertical portion 143V of the third part 143. A vertical portion 144V of the fourth part 144 may contact the vertical portion 143V of the third part 143. The vertical portion 143V of the third part 143 may contact the horizontal portion 144H and the vertical portion 144V of the fourth part 144. The end of the third part 143 may be fixed to the end of the fourth part 144. For example, the end of the third part 143 and the end of the fourth part 144 may be fixed by welding.

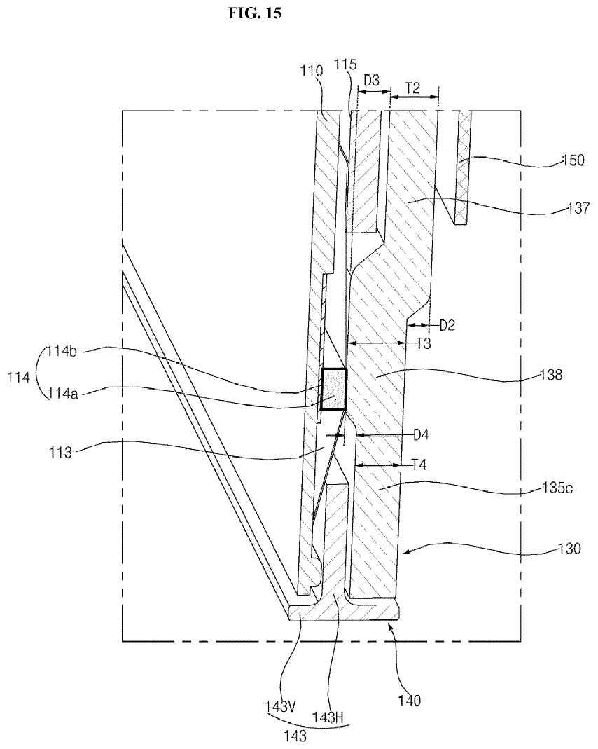

Referring to FIG. 15, the display panel 110 may be coupled or fixed on the side frame 140. The horizontal portion 143H of the side frame 140 may support a rear surface of the display panel 110, and the vertical portion 143V of the side frame 140 may cover a side surface of the display panel 110. For example, the vertical portion 143V of the third part 143 of the side frame 140 may cover a lower side surface of the display panel 110.

The vertical portion 143V may cover a side surface of the material complexed panel 130. For example, the vertical portion 143V of the third part 143 of the side frame 140 may cover a side surface of the third outer part 135c of the material complexed panel 130.

A flexible cable 113 may extend from a lower side of the display panel 110 toward between the display panel 110 and the horizontal portion 143H of the side frame 140. The flexible cable 113 may extend between the rear surface of the display panel 110 and the material complexed panel 130. For example, the flexible cable 113 may be a COF 113.

A source signal substrate 115 may be electrically connected to the flexible cable 113. The source signal substrate 115 may be fixed to one surface of the flexible cable 113. For example, the source signal substrate 115 may be an S-PCB 115. The source signal substrate 115 may be positioned in the receiving part 137 of the material complexed panel 130.

The flexible cable 113 may be positioned between the protruding pad 138 of the material complexed panel 130 and the display panel 110. The flexible cable 113 may contact the protruding pad 138. Heat generated in the source signal substrate 115 and/or the flexible cable 113 may be dissipated through the protruding pad 138.

A heat dissipation pad 114 may be positioned between the flexible cable 113 in contact with the protruding pad 138 and the rear surface of the display panel 110. The heat dissipation pad 114 may include a core 114a and a conductive film 114b. The core 114a of the heat dissipation pad 114 may be formed of an elastic material, and the conductive film 114b may cover the core 114a of the heat dissipation pad 114. Accordingly, the flexible cable 113 may be maintained in contact with the protruding pad 138.

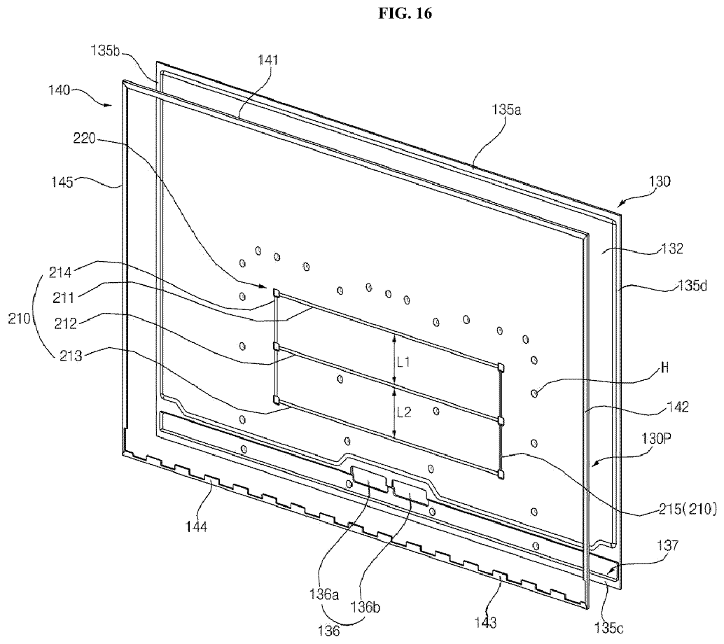

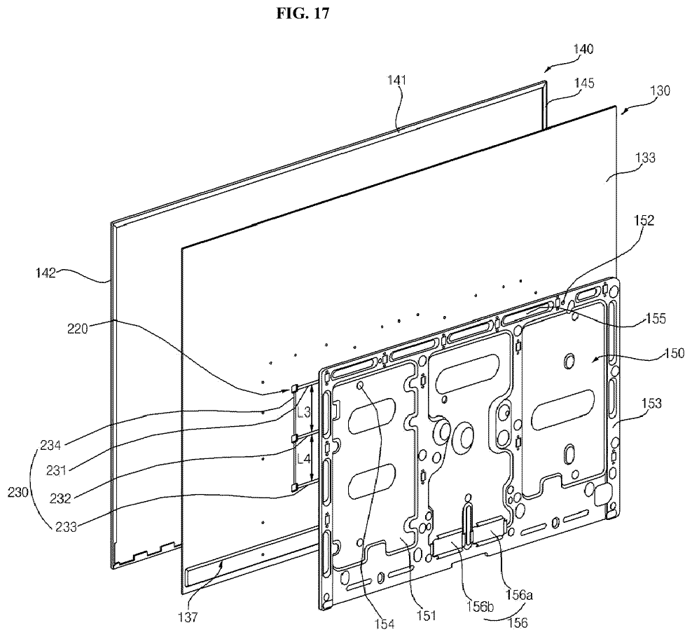

Referring to FIGS. 16 and 17, an inner frame (210, 230) may be formed on the front surface and/or the rear surface of the material complexed panel 130. The inner frame (210, 230) may be referred to as a pressed frame (210, 230) or a rigid line (210, 230). The inner frame (210, 230) may be formed in such a manner that the front skin 132 and/or the rear skin 133 of the material complexed panel 130 are recessed and the core 131 (see FIG. 2) is pressed.

The inner frame (210, 230) may include a front inner line 210, a rear inner line 230, and a node hole 220. The front inner line 210 may be formed as the front skin 132 of the material complexed panel 130 is recessed. The rear inner line 230 may be formed as the rear skin 133 of the material complexed panel 130 is recessed.

The front inner line 210 may include a first front horizontal line 211, a second front horizontal line 212, a third front horizontal line 213, a first front vertical line 214, and a second front vertical line 215. The first front horizontal line 211 may define an upper side of the front inner line 210. The third front horizontal line 213 may define a lower side of the front inner line 210. The second front horizontal line 212 may be positioned between the first front horizontal line 211 and the third front horizontal line 213. The first front vertical line 214 may connect one end of the first front horizontal line 211, one end of the second horizontal line 212, and one end of the third front horizontal line 213. The second front vertical line 215 may connect the other end of the first front horizontal line 211, the other end of the second horizontal line 212, and the other end of the third front horizontal line 213. For example, a first distance L1 between the first front horizontal line 211 and the second front horizontal line 212 may be less than a second distance L2 between the second front horizontal line 212 and the third front horizontal line 213.

The node hole 220 may be formed at a point where the front horizontal line 211, 212, 213 and the front vertical line 214, 215 meet. The node hole 220 may be formed through the front skin 132, the core 131, and the rear skin 133 of the material complexed panel 130.

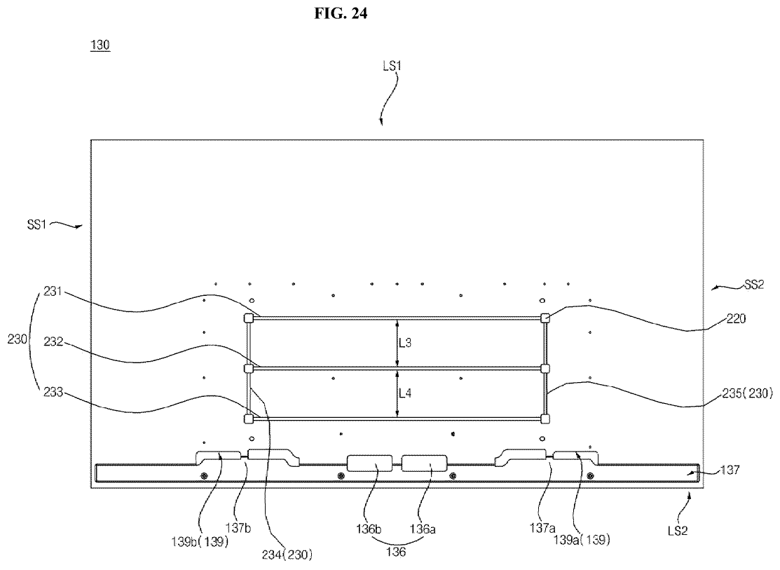

The rear inner line 230 may include a first rear horizontal line 231, a second rear horizontal line 232, a third rear horizontal line 233, a first rear vertical line 234, and a second rear vertical line 235 (see FIG. 24). The first rear horizontal line 23 1 may define an upper side of the rear inner line 230. The third rear horizontal line 233 may define a lower side of the rear inner line 230. The second rear horizontal line 232 may be positioned between the first rear horizontal line 231 and the third rear horizontal line 233. The first rear vertical line 234 may connect one end of the first rear horizontal line 231, one end of the second rear horizontal line 232, and one end of the third rear horizontal line 233. The second rear vertical line 235 (see FIG. 24) may connect the other end of the first rear horizontal line 231, the other end of the second rear horizontal line 232, and the other end of the third rear horizontal line 233. For example, a third distance L3 between the first rear horizontal line 231 and the second rear horizontal line 232 may be less than a fourth distance L4 between the second rear horizontal line 232 and the third rear horizontal line 233.

The node hole 220 may be formed at a point where the rear horizontal line 231, 232, 233 and the rear vertical line 234, 235 meet. The node hole 220 may be formed through the front skin 132, the core 131, and the rear skin 133 of the material complexed panel 130.

A length of the rear inner line 230 may be less than a length of the PCB plate 150. A width of the rear inner line 230 may be less than a width of the PCB plate PCB 150. The PCB plate 150 may cover the rear inner line 230.

Thus, it is possible to increase bending rigidity and/or torsional rigidity of the material complexed panel 130.

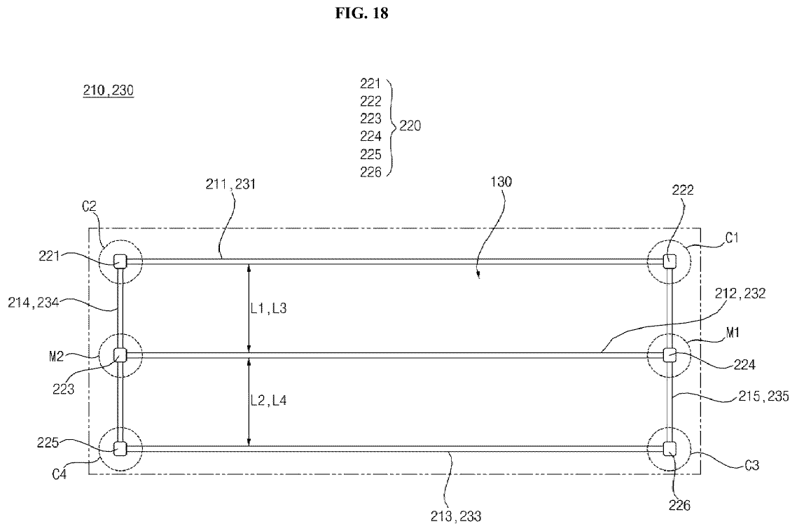

Referring to FIG. 18, a plurality of node holes 220 may be provided. The plurality of node holes 220 may include a first node hole 221, a second node hole 222, a third node hole 223, a fourth node hole 224, a fifth node hole 225, and a sixth node hole 226.

The first node hole 221 may be positioned at a corner C2 defined by the first horizontal line 211, 231 and the first vertical line 214, 234. The first node hole 221 may be formed through the material complexed panel 130 at the conner C2 between the first horizontal line 211, 231 and the first vertical line 214, 234.

The second node hole 222 may be positioned at a conner C1 defined by the first horizontal line 211, 231 and the second vertical line 215, 235. The second node hole 222 may be formed through the material complexed panel 130 at the corner C1 between the first horizontal line 211, 231 and the second vertical line 215, 235.

The third node hole 223 may be positioned at a node M2 defined by the second horizontal line 212, 232 and the first vertical line 214, 234. The third node hole 223 may be formed through the material complexed panel 130 at the node M2 between the second horizontal line 212, 232 and the first vertical line 214, 234.

The fourth node hole 224 may be positioned at a node M1 defined by the second horizontal line 212, 232 and the second vertical line 215, 235. The fourth node hole 224 may be formed through the material complexed panel 130 at the node MI between the second horizontal line 212, 232 and the second vertical line 215, 235.

The fifth node hole 225 may be positioned at a corner C4 defined by the third horizontal line 213, 233 and the first vertical line 214, 234. The fifth node hole 225 may be formed through the material complexed panel 130 at the corner C4 between the third horizontal line 213, 233 and the first vertical line 214, 234.

The sixth node hole 226 may be positioned at a corner C3 defined by the third horizontal line 213, 233 and the second vertical line 215, 235. The sixth node hole 226 may be formed through the material complexed panel 130 at the corner C3 between the third horizontal line 213, 233 and the second vertical line 215, 235.

Thus, it is possible to not only increase bending rigidity and/or torsional rigidity of the material complexed panel 130, but also to improve flatness of the display panel 110 coupled to the material complexed panel 130.

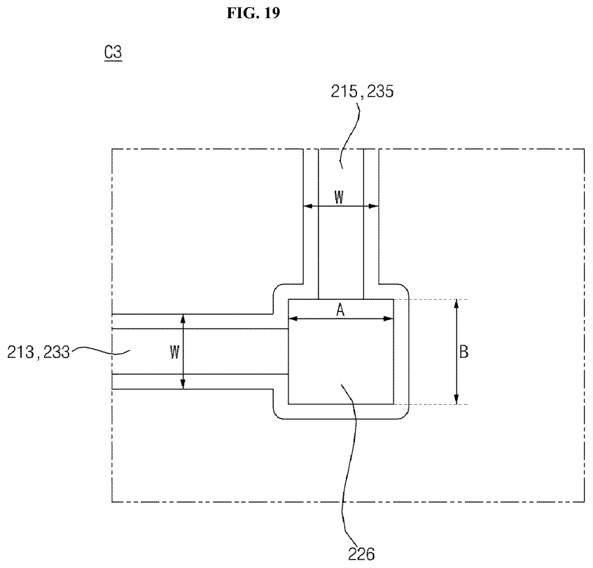

Referring to FIG. 19, the sixth node hole 226 may have a size greater than a width of the third horizontal line 213, 233 and/or the second vertical line 215, 235. For example, when the sixth node hole 226 is of a quadrilateral shape, a width A, B of the node hole 226 may be greater than a width W of the third horizontal line 213, 233 and/or the second vertical line 215, 235. As another example, when the sixth node hole 226 is of a circular shape, a diameter of the sixth node hole 226 may be greater than the width of the third horizontal line 213, 233 and/or the second vertical line 215, 235. The description of the sixth node hole 226 is equally applicable to the first node hole 221, the second node hole 222, and/or the fifth node hole 225.

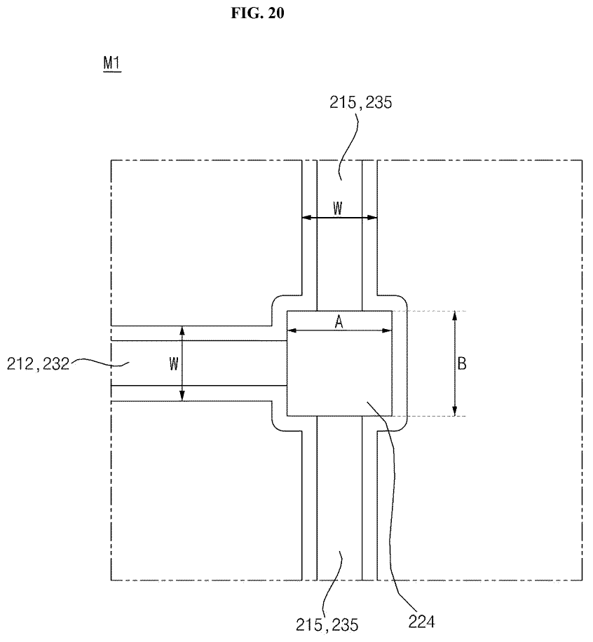

Referring to FIG. 20, the fourth node hole 224 may have a size greater than a width of the second horizontal line 212, 232 and/or the second vertical line 215, 235. For example, when the fourth node hole 224 is of a quadrilateral shape, a width A, B of the fourth node hole 224 may be greater than a width W of the second horizontal line 212, 232 and/or the second vertical line 215, 235. As another example, when the fourth node hole 224 is of a circular shape, a diameter of the fourth node hole 224 may be greater than the width of the second horizontal line 212, 232 and/or the second vertical line 215, 235. The description of the fourth node hole 224 is equally appliable to the third node hole 223.

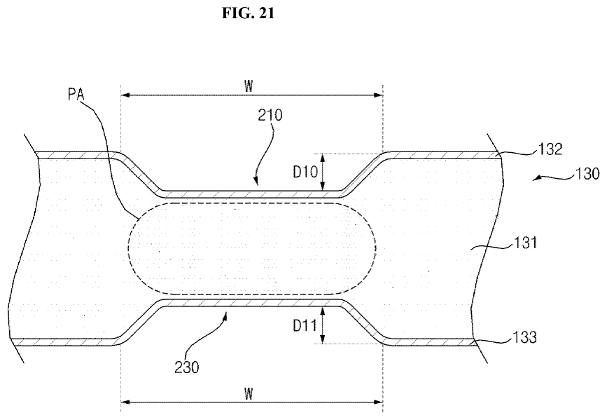

Referring to FIG. 21, the front skin 132 may be recessed as the core 131 is pressed, so that the front inner line 210 may be formed on the material complexed panel 130. The rear skin 133 may be recessed as the core 131 is pressed, so that the rear inner line 230 may be formed on the material complexed panel 130.

The front inner line 210 and the rear inner line 230 may be symmetric with respect to the core 131. For example, a width W of the front inner line 210 may be substantially equal to a width W of the rear inner line 230. As another example, a depth D10 of the front inner line 210 may be substantially equal to a depth D11 of the rear inner line 230.

A pressed area PA caused by the core 131 being pressed may be formed between the front inner line 210 and the rear inner line 230. The density of the core 131 in the pressed area PA may be greater than the density of the core 131 in a non-pressed area.

Thus, it is possible to increase bending rigidity and/or torsional rigidity of the material complexed panel 130.

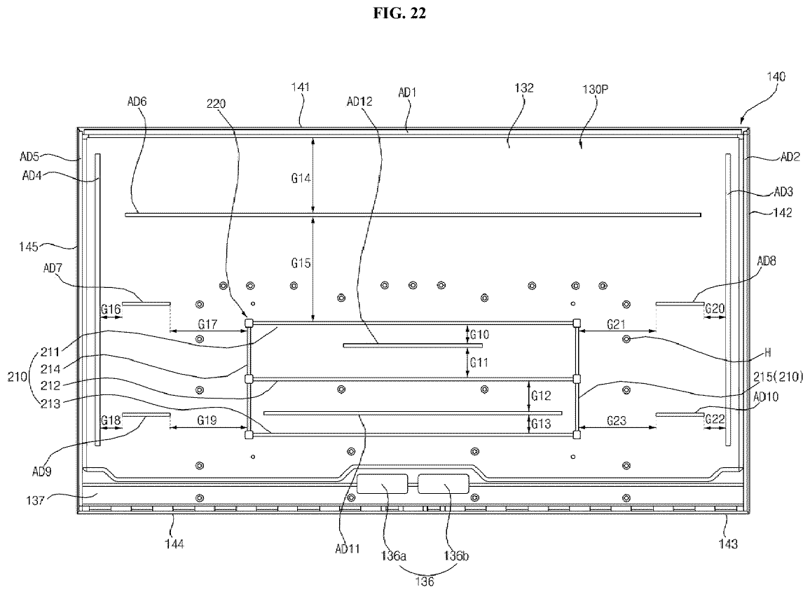

Referring to FIG. 22, an adhesive member AD may be disposed on the flat part 130P of the material complexed panel 130. The adhesive member AD may be attached to the front skin 132 of the material complexed panel 130. The adhesive member AD may be provided in plurality.

A first adhesive member AD1 may be fixed to the first part 141 of the side frame 140. The first adhesive member AD1 may be elongated along a longitudinal direction of the first part 141 of the side frame 140. A second adhesive member AD2 may be elongated along a longitudinal direction of the second part 142 of the side frame 140, and may be fixed to the second part 142. A third adhesive member AD3 may be elongated along the second part 142 of the side frame 140, may be parallel to the second part 142, and may be fixed to the flat part 130P while being spaced apart from the first adhesive member AD1.

A fifth adhesive member AD5 may be elongated along a longitudinal direction of the fifth part 145 of the side frame 140, and may be fixed to the fifth part 145. A fourth adhesive member AD4 may be elongated along the fifth part 145 of the side frame 140, may be parallel to the fifth part 145, and may be fixed to the flat part 130P while being spaced apart from the fifth adhesive member AD5.

A sixth adhesive member AD6 may be elongated along the longitudinal direction of the first part 141 of the side frame 140, and may be fixed to the flat part 130P while being spaced apart from the first adhesive member AD1. A fourteenth distance G14 from the first part 141 of the side frame 140 to the sixth adhesive member AD6 may be less than a fifteenth distance G15 from the sixth adhesive member AD6 to the first front horizontal inner line 211.

A seventh adhesive member AD7 may extend along a longitudinal direction of the sixth adhesive member AD6, and may be fixed to the flat part 130P between the first front vertical line 214 and the fourth adhesive member AD4. The seventh adhesive member AD7 may be positioned between the sixth adhesive member AD6 and a ninth adhesive member AD9. A sixteenth distance G16 from the fourth adhesive member AD4 to one end of the seventh adhesive member AD7 may be less than a seventeenth distance G17 from the first front vertical line 214 to the other end of the seventh adhesive member AD7.

The ninth adhesive member AD9 may extend along the longitudinal direction of the sixth adhesive member AD6, and may be fixed to the flat part 130P between the first front vertical line 214 and the fourth adhesive member AD4. The ninth adhesive member AD9 may be positioned between the seventh adhesive member AD7 and the receiving part 137. An eighteenth distance G18 from the fourth adhesive member AD4 to one end of the ninth adhesive member AD9 may be less than a nineteenth distance G19 from the first front vertical line 214 to the other end of the ninth adhesive member AD9.

An eighth adhesive member AD8 may extend along the longitudinal direction of the sixth adhesive member AD6, and may be fixed to the flat part 130P between the second front vertical line 215 and the third adhesive member AD3. The eighth adhesive member AD8 may be positioned between the sixth adhesive member AD6 and the receiving part 137. A twentieth distance G20 from the third adhesive member AD3 to one end of the eighth adhesive member AD8 may be less than a twenty-first distance G21 from the second front vertical line 215 to the other end of the eighth adhesive member AD8.

A tenth adhesive member AD10 may extend along the longitudinal direction of the sixth adhesive member AD6, and may be fixed to the flat part 130P between the second front vertical line 215 and the third adhesive member AD3. The tenth adhesive member AD10 may be positioned between the eighth adhesive member AD8 and the receiving part 137. A twenty-second distance G22 from the third adhesive member AD3 to one end of the tenth adhesive member AD10 may be less than a twenty-third distance G23 from the second front vertical line 215 to the other end of the tenth adhesive member AD10.

An eleventh adhesive member AD11 may be elongated along a longitudinal direction of the second front horizontal line 212, and may be fixed to the flat part 130P between the second front horizontal line 212 and the third front horizontal line 213. A twelfth adhesive member AD12 may be elongated along the longitudinal direction of the second front horizontal line 212, and may be fixed to the flat part 130P between the first front horizontal line 211 and the second front horizontal line 212. A length of the twelfth adhesive member AD12 may be less than a length of the eleventh adhesive member AD11.

A tenth distance G10 between the first front horizontal line 211 and the twelfth adhesive member AD12 may be less than an eleventh distance G11 between the twelfth adhesive member AD12 and the second front horizontal line 212. For example, the tenth distance G10 may be 40 mm or more. For example, a distance between one end of the twelfth adhesive member AD12 and the first vertical front line 214 may be 20 mm or more. As another example, a distance between the other end of the twelfth adhesive member AD12 and the second vertical front line 215 may be 20 mm or more.

A twelfth distance G12 between the second front horizontal line 212 and the eleventh adhesive member AD11 may be greater than a thirteenth distance G13 between the eleventh adhesive member AD11 and the third front horizontal line 213. For example, the thirteenth distance G13 may be 40 mm or more.

The display panel 110 may be coupled or fixed to the material complexed panel 130 by the adhesive member AD. Accordingly, the display panel 110 may be fixed to the material complexed panel 130 in a flat manner.

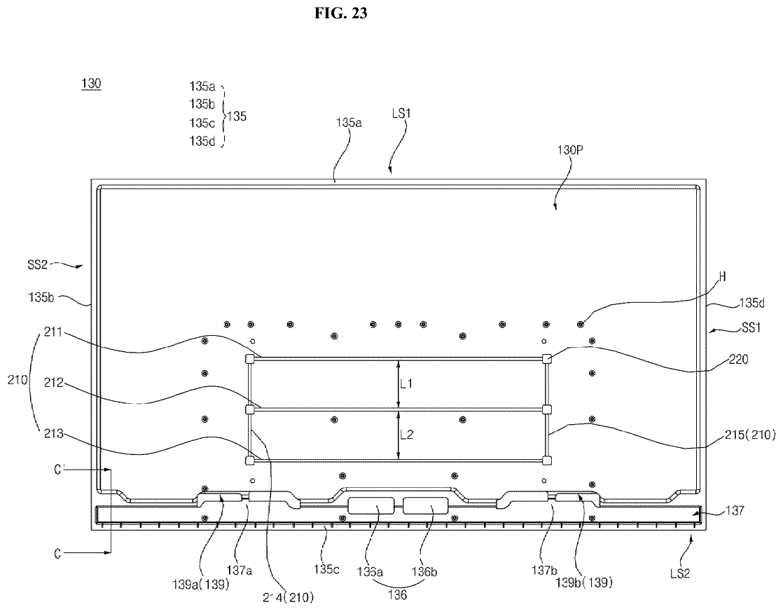

Referring to FIGS. 23 and 24, the material complexed panel 130 may include a flat part 130P, a receiving part 137, and an outer part 135. The outer part 135 may be formed around the flat part 130P, and may define an edge of the material complexed panel 130. A first outer part 135a may be formed along an upper side of the flat part 130P, a second outer part 135b may be formed along a left side of the flat part 130P, a third outer part 135c may be formed along a lower side of the flat part 130P, and a fourth outer part 135d may be formed along a right side of the flat part 130P. The outer part 135 may be formed as the flat part 130P is pressed. The outer part 135 may be lowered from the flat part 130P to thereby form a step. The flat part 130P may have a greater thickness than the outer part 135. The lower side of the flat part 130P may form a line with a curve.

The receiving part 137 may be formed on the third outer part 135c while being adjacent to the lower side of the flat part 130P. The receiving part 137 may be provided in plurality. A first receiving part 137a may be positioned between a first cable hole 136a and the second short side SS2. A second receiving part 137b may be positioned between a second cable hole 136b and the first short side SS1. The first receiving part 137a may be connected to the second receiving part 137b. The receiving part 137 may be formed as the third outer part 135c is pressed from the front to the rear. The receiving part 137 may form a step descending from a front surface of the third outer part 135c.

A cable hole 136 may be formed through the front skin 132 (see FIG. 2) and the rear skin 133 (see FIG. 2) of the receiving part 137. The cable hole 136 may be formed in the receiving part 137 and/or the third outer part 135c while being adjacent to the lower side of the flat part 130P. The cable hole 136 may be provided in plurality. The first cable hole 136a and the second cable hole 136b may be positioned adjacent to each other.

An inner frame (210, 230) may be formed on the front surface and/or the rear surface of the material complexed panel 130. The inner frame (210, 230) may be referred to as a pressed frame (210, 230) or a rigid line (210, 230). The inner frame (210, 230) may be formed in such a manner that the front skin 132 and/or the rear skin 133 of the material complexed panel 130 are recessed and the core 131 (see FIG. 2) is pressed.

The inner frame (210, 230) may include a front inner line 210, a rear inner line 230, and a node hole 220. The front inner line 210 may be formed as the front skin 132 of the material complexed panel 130 is recessed. The rear inner line 230 may be formed as the rear skin 133 of the material complexed panel 130 is recessed.

The front inner line 210 may include a first front horizontal line 211, a second front horizontal line 212, a third front horizontal line 213, a first front vertical line 214, and a second front vertical line 215. The first front horizontal line 211 may define an upper side of the front inner line 210. The third front horizontal line 213 may define a lower side of the front inner line 210. The second front horizontal line 212 may be positioned between the first front horizontal line 211 and the third front horizontal line 213. The first front vertical line 214 may connect one end of the first front horizontal line 211, one end of the second front horizontal line 212, and one end of the third front horizontal line 213. The second front vertical line 215 may connect the other end of the first front horizontal line 211, the other end of the second front horizontal line 212, and the other end of the third front horizontal line 213. For example, a first distance L1 between the first front horizontal line 211 and the second front horizontal line 212 may be less than a second distance L2 between the second front horizontal line 212 and the third front horizontal line 213.

The node hole 220 may be formed at a point where the front horizontal line 211, 212, 213 and the front vertical line 214, 215 meet. The node hole 220 may be formed through the front skin 132, the core 131, and the rear skin 133 of the material complexed panel 130.

The rear inner line 230 may include a first rear horizontal line 231, a second rear horizontal line 232, a third rear horizontal line 233, a first rear vertical line 234, and a second rear vertical line 235. The first rear horizontal line 231 may define an upper side of the rear inner line 230. The third rear horizontal line 233 may define a lower side of the rear inner line 230. The second rear horizontal line 232 may be positioned between the first rear horizontal line 231 and the third rear horizontal line 233. The first rear vertical line 234 may connect one end of the first rear horizontal line 231, one end of the second rear horizontal line 232, and one end of the third rear horizontal line 233. The second rear vertical line 235 may connect the other end of the first rear horizontal line 231, the other end of the second rear horizontal line 232, and the other end of the third rear horizontal line 233. For example, a third distance L3 between the first rear horizontal line 231 and the second rear horizontal line 232 may be less than a fourth distance L4 between the second rear horizontal line 232 and the third rear horizontal line 233.

The node hole 220 may be formed at a point where the rear horizontal line 231, 232, 233 and the rear vertical line 234, 235 meet. The node hole 220 may be formed through the front skin 132, the core 131, and the rear skin 133 of the material complexed panel 130.

The receiving part 137 may be formed as the third outer part 135c is pressed from the front to the rear. The receiving part 137 may form a step ascending from a rear surface of the third outer part 135c.

A cut-out portion 139 may be formed on at least a portion of the curved line defined along the lower side of the flat part 130P. The cut-out portion 39 may be provided in plurality. A first cut-out portion 139a may be aligned to the first receiving part 137a, and a second cut-out portion 139b may be aligned to the second receiving part 137b. The cut-out portion 139 may be formed on a line defining a step between a front surface of the flat part 130P and the third outer part 135c. The cut-out portion 139 may be formed on a line defining a step between the third outer part 135c and the receiving part 137.

Thus, it is possible to not only increase bending rigidity and/or torsional rigidity of the material complexed panel 130, but also to improve flatness of the material complexed panel 130.

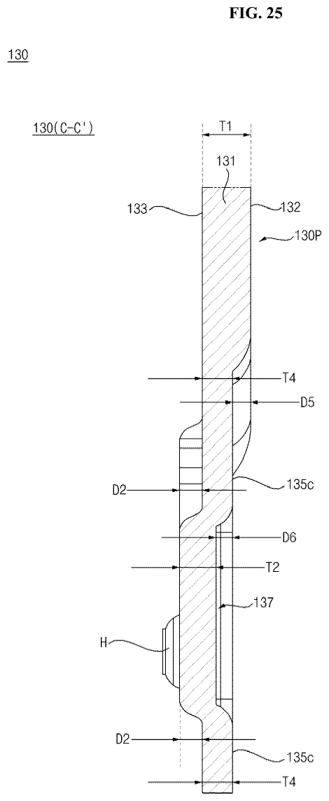

Referring to FIG. 25, the third outer part 135c may be formed as the flat part 130P is pressed. The front skin 132 of the third outer part 135c may form a step D5 descending from the front skin 132 of the flat part 130P.

The receiving part 137 may be formed as the third outer part 135c is pressed. The front skin 132 of the receiving part 137 may form a step D6 descending from the front skin 132 of the third outer part 135c.

The rear skin 133 of the receiving part 137 may form a step D2 ascending from the rear skin 133 of the third outer part 135c. For example, a height of the step D6 descending from the front skin 132 of the third outer part 135c to the front skin 132 of the receiving part 137 may be less than a height of the step D2 ascending from the rear skin 133 of the third outer part 135c to the rear skin 133 of the receiving part 137. A thickness T1 of the flat part 130P may be greater than a thickness T2 of the receiving part 137. A thickness T4 of the third outer part 135c may be less than the thickness T1 of the flat part 130P. The thickness T2 of the receiving part 137 may be greater than the thickness T4 of the third outer part 135c.

As the core 131 of the material complexed panel 130 is pressed in a direction from the front skin 132 to the rear skin 133 of the flat part 130P, the core 131 may absorb an external force. The magnitude of the external force applied to the front skin 132 of the flat part 130P may be greater than the magnitude of the external force applied to the rear skin 133 of the flat part 130P. The core 131 of the material complexed panel 130 may absorb impact as well as achieve rigidity.

A fastening groove H may protrude from the rear skin 133 of the receiving part 137. The fastening groove H may be recessed in the front skin 132 of the receiving part 137 and may protrude from the rear skin 133 of the receiving part 137. A central portion of the fastening groove H may be penetrated.

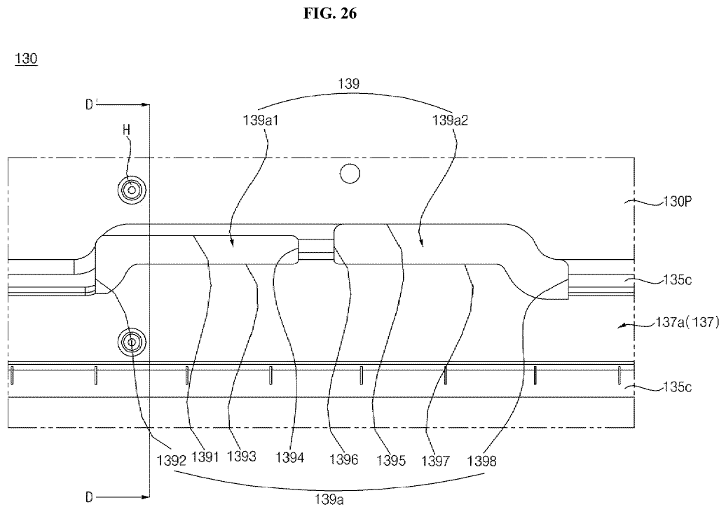

Referring to FIG. 26, the first cut-out portion 139a may include a first slit 139a1 and a second slit 139a2. The first slit 139a1 and/or the second slit 139a2 may be elongated in a longitudinal direction of the receiving part 137. The first slit 139a1 may be formed at a boundary of the flat part 130P, a boundary of the third outer part 135c, and/or a boundary of the first receiving part 137a. The second slit 139a2 may be formed at the boundary of the flat part 130P, the boundary of the third outer part 135c, and/or the boundary of the first receiving part 137a while being adjacent to the first slit 139a1.

The first slit 139a1 may include an upper side 1391, a left side 1392, a right side 1394, and a lower side 1393. The upper side 1391 may be formed in a step region formed at a lower side boundary of the flat part 130P. The lower side 1393 may be formed in the first receiving part 137a while being adjacent to an upper side of the first receiving part 137a. The left side 1392 may connect a left end of the upper side 1391 and a left end of the lower side 1393, and may be formed in a step region at the lower side of the flat part 130P, the third outer part 135c, and/or the first receiving part 137a. The right side 1394 may be formed in a step region formed at the lower side boundary of the flat part 130P, the third outer part 135c, and/or the first receiving part 137a. For example, a length of the left side 1392 may be greater than a length of the right side 1394, the upper side 1391 may define a straight line, and the lower side 1393 may include a straight line and a curved line.

The second slit 139a2 may include an upper side 1395, a left side 1396, a right side 1398, and a lower side 1397. The upper side 1395 may be formed at the lower side boundary of the flat part 130P. The lower side 1397 may be formed in the first receiving part 137a while being adjacent to the upper side of the first receiving part 137a. The left side 1396 may connect a left end of the upper side 1395 and a left end of the lower side 1397, and may be formed in a step region at the lower side of the flat part 130P, the third outer part 135c, and/or the first receiving part 137a. The right side 1398 may be formed in a step region formed at the lower side boundary of the flat part 130P, the third outer part 135c, and/or the first receiving part 137a. For example, a length of the left side 1396 may be substantially equal to a length of the right side 1398, the upper side 1395 may include a straight line and a curved line, and the lower side 1397 may include a straight line and a curved line. The upper side 1395 and the lower side 1397 may be parallel to each other.

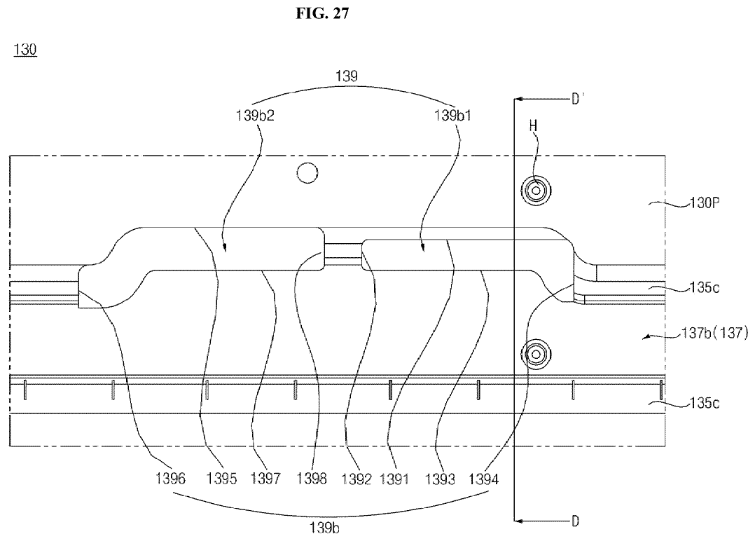

Referring to FIG. 27, the second cut-out portion 139b may include a first slit 139b1 and a second slit 139b2. The first slit 139b1 and/or the second slit 139b2 may be elongated in the longitudinal direction of the receiving part 137. The first slit 139b1 may be formed at a boundary of the flat part 130P, a boundary of the third outer part 135c, and/or a boundary of the second receiving part 137b. The second slit 139b2 may be formed at the boundary of the flat part 130P, the boundary of the third outer part 135c, and/or the boundary of the second receiving part 137b while being adjacent to the first slit 139b1.

The first slit 139b1 may include an upper side 1391, a left side 1392, a right side 1394, and a lower side 1393. The upper side 1391 may be formed in a step region formed at a lower side boundary of the flat part 130P. The lower side 1393 may be formed in the second receiving part 137b while being adjacent to an upper side of the second receiving part 137b. The left side 1392 may connect a left end of the upper side 1391 and a left end of the lower side 1393, and may be formed in a step region at the lower side of the flat part 130P, the third outer part 135c, and/or the second receiving part 137b. The right side 1394 may be formed in a step region formed at the lower side boundary of the flat part 130P, the third outer part 135c, and/or the second receiving part 137b. For example, a length of the left side 1392 may be greater than a length of the right side 1394, the upper side 1391 may define a straight line, and the lower side 1393 may include a straight line and a curved line.

The second slit 139b2 may include an upper side 1395, a left side 1396, a right side 1398, and a lower side 1397. The upper side 1395 may be formed at the lower side boundary of the flat part 130P. The lower side 1397 may be formed in the second receiving part 137b while being adjacent to the upper side of the second receiving part 137b. The left side 1396 may connect a left end of the upper side 1395 and a left end of the lower side 1397, and may be formed in a step region at the lower side of the flat part 130P, the third outer part 135c, and/or the second receiving part 137b. The right side 1398 may be formed in a step region formed at the lower side boundary of the flat part 130P, the third outer part 135c, and/or the second receiving part 137b. For example, a length of the left side 1396 may be substantially equal to a length of the right side 1398, the upper side 1395 may include a straight line and a curved line, and the lower side 1397 may include a straight line and a curved line. The upper side 1395 and the lower side 1397 may be parallel to each other.

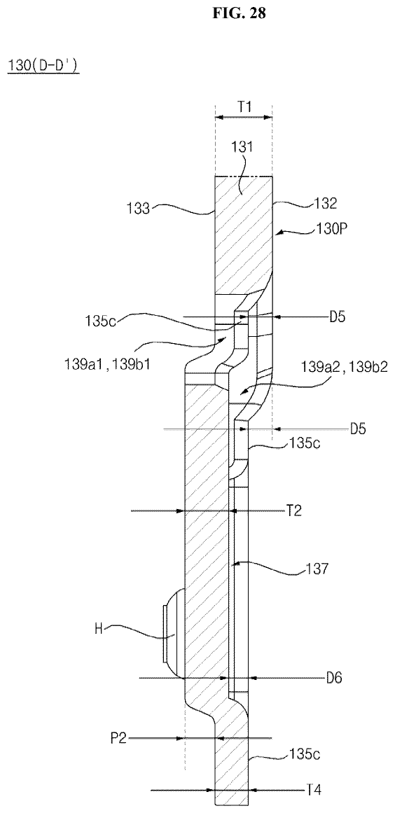

Referring to FIG. 28, the third outer part 135c may be formed as the flat part 130P is pressed. The front skin 132 of the third outer part 135c may form a step D5 descending from the front skin 132 of the flat part 130P.

The receiving part 137 may be formed as the third outer part 135c is pressed. The front skin 132 of the receiving part 137 may form a step D6 descending from the front skin 132 of the third outer part 135c.

The rear skin 133 of the receiving part 137 may form a step D2 ascending from the rear skin 133 of the third outer part 135c. For example, a height of the step D6 descending from the front skin 132 of the third outer part 135c to the front skin 132 of the receiving part 137 may be less than a height of the step D2 ascending from the rear skin 133 of the third outer part 135c to the rear skin 133 of the receiving part 137. A thickness T1 of the flat part 130P may be greater than a thickness T2 of the receiving part 137. A thickness T4 of the third outer part 135c may be less than the thickness T1 of the flat part 130P. The thickness T2 of the receiving part 137 may be greater than the thickness T4 of the third outer part 135c.

As the core 131 of the material complexed panel 130 is pressed in a direction from the front skin 132 to the rear skin 133 of the flat part 130P, the core 131 may absorb an external force. The magnitude of the external force applied to the front skin 132 of the flat part 130P may be greater than the magnitude of the external force applied to the rear skin 133 of the flat part 130P. The core 131 of the material complexed panel 130 may absorb impact as well as achieve rigidity.

A fastening groove H may protrude from the rear skin 133 of the receiving part 137. The fastening groove H may be recessed in the front skin 132 of the receiving part 137 and may protrude from the rear skin 133 of the receiving part 137. A central portion of the fastening groove H may be penetrated.

The first slit 139a1, 139b1 may be formed through the front skin 132, the core 131, and/or the rear skin 133. The second slit 139a2, 139b2 may be formed through the front skin 132, the core 131, and/or the rear skin 133.

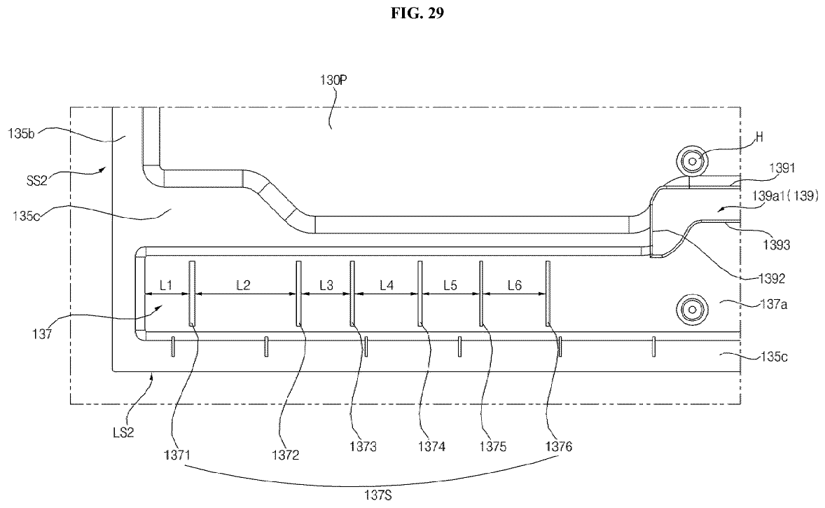

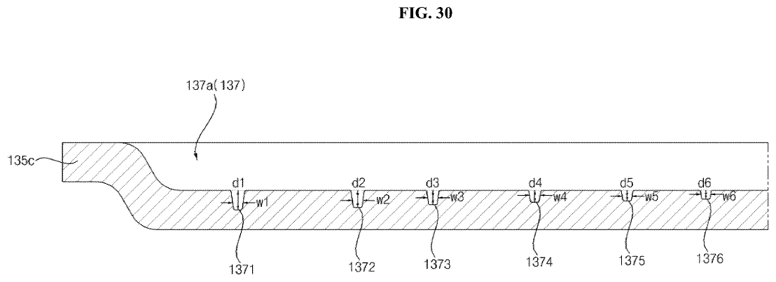

Referring to FIGS. 29 and 30, a slit groove 137s may be formed on the receiving part 137, 137a. The slit groove 137s may be elongated in a widthwise direction of the receiving part 137. The slit groove 137s may be formed as the front skin 132 (see FIG. 28) of the receiving part 137 is recessed. The slit groove 137s may be formed as the front skin 132 of the receiving part 137 is pressed. The slit groove 137s may be provided in plurality. The slit groove 137s may be referred to as a pressed line 137s, a pressed slit 137s, a vertical line 137s, or a vertical slit 137s.

A first slit groove 1371 may extend in the widthwise direction of the receiving part 137, and may be disposed closest to the second short side SS2 among the plurality of slits 137s so as to be formed on the receiving part 137. A second slit groove 1372 may be disposed between the first slit 139a1 and the first slit groove 1371 so as to be formed on the receiving part 137. A third slit groove 1373 may be disposed between the second slit groove 1372 and the first slit 139a1 so as to be formed on the receiving part 137. A fourth slit groove 1374 may be disposed between the third slit groove 1373 and the first slit 139a1 so as to be formed on the receiving part 137. A sixth slit groove 1376 may be disposed between the fifth slit groove 1375 and the first slit 139a1 so as to be formed on the receiving part 137. The slit grooves 137s may have substantially the same length.

A first distance L1 between a step end of the receiving part 137, which is adjacent to the second short side SS2, and the first slit groove 1371 may be less than a second distance L2 between the first slit groove 1371 and the second slit groove 1372. For example, the first distance L1 may be about 3 cm, and the second distance L2 may be about 5 cm.

A third distance L3 between the second slit groove 1372 and the third slit groove 1373 may be less than the first distance L1. For example, the third distance L3 may be about 2 cm.

A fourth distance L4 between the third slit groove 1373 and the fourth slit groove 1374 may be greater than the third distance L3 and substantially equal to the first distance L1. For example, the fourth distance L4 may be about 3 cm.

A fifth distance L5 between the fourth slit groove 1374 and the fifth slit groove 1375 may be greater than the third distance L3 and less than the fourth distance L4. For example, the fifth distance L5 may be about 2.5 cm.

A sixth distance L6 between the fifth slit groove 1375 and the sixth slit groove 1376 may be substantially equal to the fifth distance L5. For example, the sixth distance L6 may be about 2.5 cm.

A width W1 and/or a depth d1 of the first slit groove 1371 may be greater than a width W2 and/or a depth d2 of the second slit groove 1372. The width W2 and/or the depth d2 of the second slit groove 1372 may be greater than a width W3 and/or a depth d3 of the third slit groove 1373. The width W3 and/or the depth d3 of the third slit groove 1373 may be greater than a width W4 and/or a depth d4 of the fourth slit groove 1374. The width W4 and/or the depth d4 of the fourth slit groove 1374 may be greater than a width W5 and/or a depth d5 of the fifth slit groove 1375. The width W5 and/or the depth d5 of the fifth slit groove 1375 may be greater than a width W6 and/or a depth d6 of the sixth slit groove 1376.

The receiving part 137, which is formed by pressing the third outer part 135c, may not be flat as the core 131 of the material complexed panel 130 absorbs an impact caused by pressing. The slit grooves 137s may allow the flatness of the receiving part 137 to be improved.

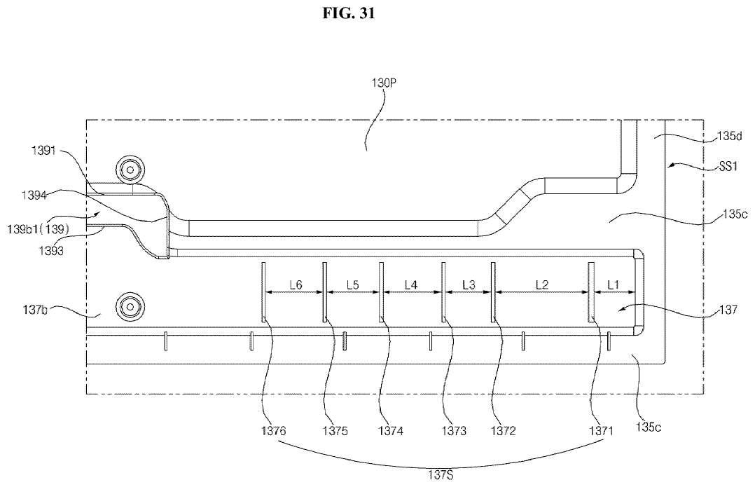

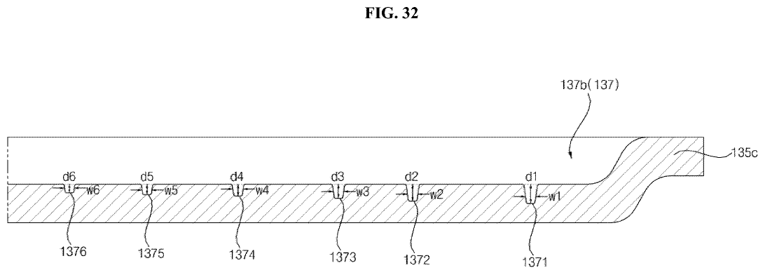

Referring to FIGS. 31 and 32, a slit groove 137s may be formed on the receiving part 137, 137b. The slit groove 137s may be elongated in the widthwise direction of the receiving part 137. The slit groove 137s may be formed as the front skin 132 (see FIG. 28) of the receiving part 137 is recessed. The slit groove 137s may be formed as the front skin 132 of the receiving part 137 is pressed. The slit groove 137s may be provided in plurality. The slit groove 137s may be referred to as a pressed line 137s, a pressed slit 137s, a vertical line 137s, or a vertical slit 137s.

A first slit groove 1371 may extend in the widthwise direction of the receiving part 137, and may be disposed closest to the first short side SS2 among the plurality of slits 137s so as to be formed on the receiving part 137. A second slit groove 1372 may be disposed between the first slit 139b1 and the first slit groove 1371 so as to be formed on the receiving part 137. A third slit groove 1373 may be disposed between the second slit groove 1372 and the first slit 139b1 so as to be formed on the receiving part 137. A fourth slit groove 1374 may be disposed between the third slit groove 1373 and the first slit 139b1 so as to be formed on the receiving part 137. A fifth slit groove 1375 may be disposed between the fourth slit groove 1374 and the first slit 139b1 so as to be formed on the receiving part 137. A sixth slit groove 1376 may be disposed between the fifth slit groove 1375 and the first slit 39b1 so as to be formed on the receiving part 137. The slit grooves 137s may have substantially the same length.

A first distance L1 between a step end of the receiving part 137, which is adjacent to the first short side SS1, and the first slit groove 1371 may be less than a second distance L2 between the first slit groove 1371 and the second slit groove 1372. For example, the first distance L1 may be about 3 cm, and the second distance L2 may be about 5 cm.

A third distance L3 between the second slit groove 1372 and the third slit groove 1373 may be less than the first distance L1. For example, the third distance L3 may be about 2 cm.

A fourth distance L4 between the third slit groove 1373 and the fourth slit groove 1374 may be greater than the third distance L3 and substantially equal to the first distance L1. For example, the fourth distance L4 may be about 3 cm.

A fifth distance L5 between the fourth slit groove 1374 and the fifth slit groove 1375 may be greater than the third distance L3 and less than the fourth distance L4. For example, the fifth distance L5 may be about 2.5 cm.

A sixth distance L6 between the fifth slit groove 1375 and the sixth slit groove 1376 may be substantially equal to the fifth distance L5. For example, the sixth distance L6 may be about 2.5 cm.

A width W1 and/or a depth d1 of the first slit groove 1371 may be greater than a width W2 and/or a depth d2 of the second slit groove 1372. The width W2 and/or the depth d2 of the second slit groove 1372 may be greater than a width W3 and/or a depth d3 of the third slit groove 1373. The width W3 and/or the depth d3 of the third slit groove 1373 may be greater than a width W4 and/or a depth d4 of the fourth slit groove 1374. The width W4 and/or the depth d4 of the fourth slit groove 1374 may be greater than a width W5 and/or a depth d5 of the fifth slit groove 1375. The width W5 and/or the depth d5 of the fifth slit groove 1375 may be greater than a width W6 and/or a depth d6 of the sixth slit groove 1376.

The receiving part 137, which is formed by pressing the third outer part 135c, may not be flat as the core 131 of the material complexed panel 130 absorbs an impact caused by pressing. The slit grooves 137s may allow the flatness of the receiving part 137 to be improved.

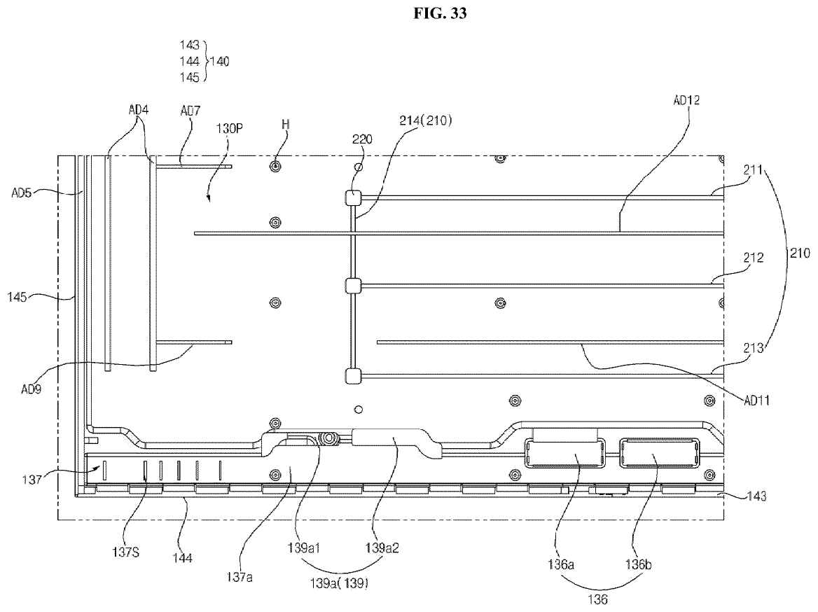

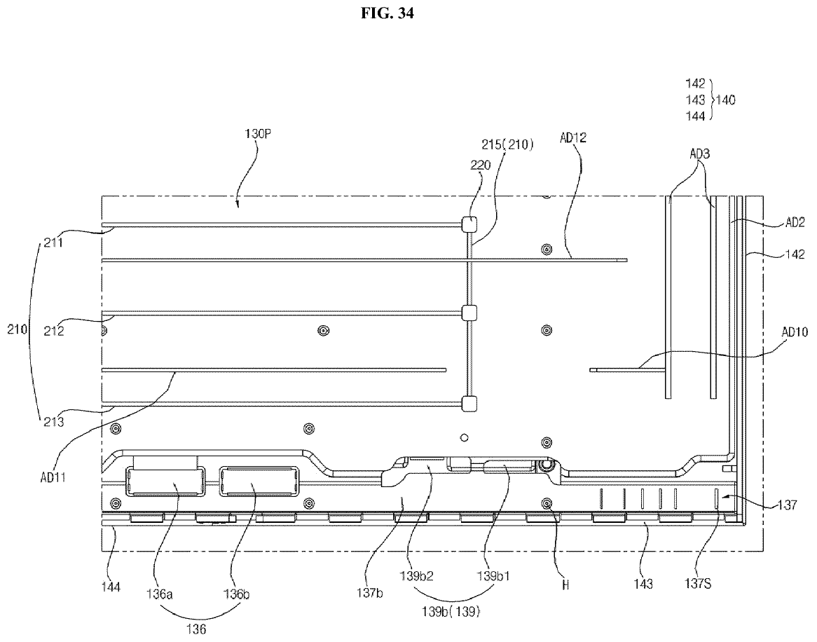

Referring to FIGS. 33 and 34, the side frame 140 may be coupled to the outer part 135 (see FIG. 23) while being adjacent to the flat part 130P. The side frame 140 may include a first part 141 (see FIG. 16), a second part 142, a third part 143, a fourth part 144, and a fifth part 145.

A front inner line 210 may include a first front horizontal line 211, a second front horizontal line 212, a third front horizontal line 213, a first front vertical line 214, and a second front vertical line 215. The first front horizontal line 211 may define an upper side of the front inner line 210. The third front horizontal line 213 may define a lower side of the front inner line 210. The second front horizontal line 212 may be positioned between the first front horizontal line 211 and the third horizontal line 213. The first front vertical line 214 may connect one end of the first front horizontal line 211, one end of the second front horizontal line 212, and one end of the third front horizontal line 213. The second front vertical line 215 may connect the other end of the first front horizontal line 211, the other end of the second front horizontal line 212, and the other end of the third front horizontal line 213.

A node hole 220 may be formed at a point where the front horizontal line 211, 212, 213 and the front vertical line 214, 215 meet. The node hole 220 may be formed through the front skin 132, the core 131, and the rear skin 133 of the material complexed panel 130.

A cut-out portion 139 may be formed on at least a portion of the curved line defined along the lower side of the flat part 130P. The cut-out portion 39 may be provided in plurality. A first cut-out portion 139a may be aligned to the first receiving part 137a, and a second cut-out portion 139b may be aligned to the second receiving part 137b. The cut-out portion 139 may be formed on a line defining a step between a front surface of the flat part 130P and the third outer part 135c. The cut-out portion 139 may be formed on a line defining a step between the third outer part 135c and the receiving part 137.

A slit groove 137s may be formed on the receiving part 137. The slit groove 137s may be elongated in a widthwise direction of the receiving part 137. The slit groove 137s may be formed as the front skin 132 (see FIG. 28) of the receiving part 137 is recessed. The slit groove 137s may be provided in plurality.

Thus, it is possible to not only increase bending rigidity and/or torsional rigidity of the material complexed panel 130, but also to improve flatness of the material complexed panel 130.

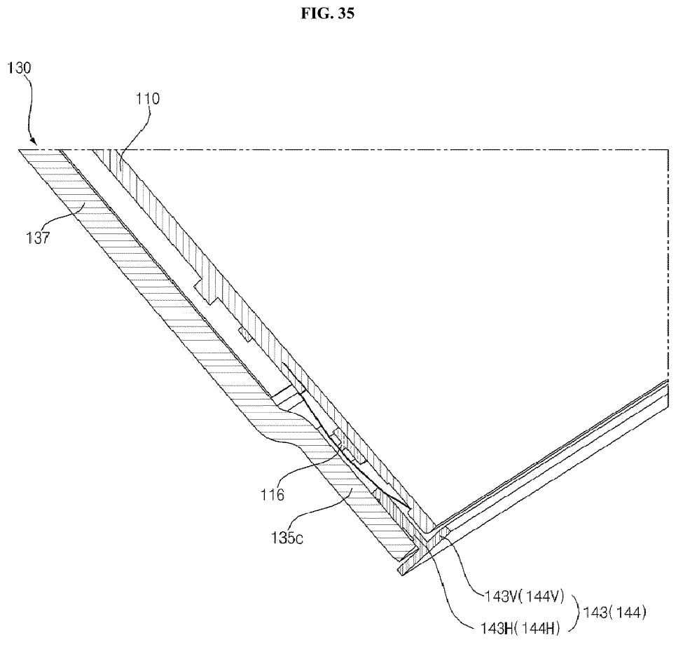

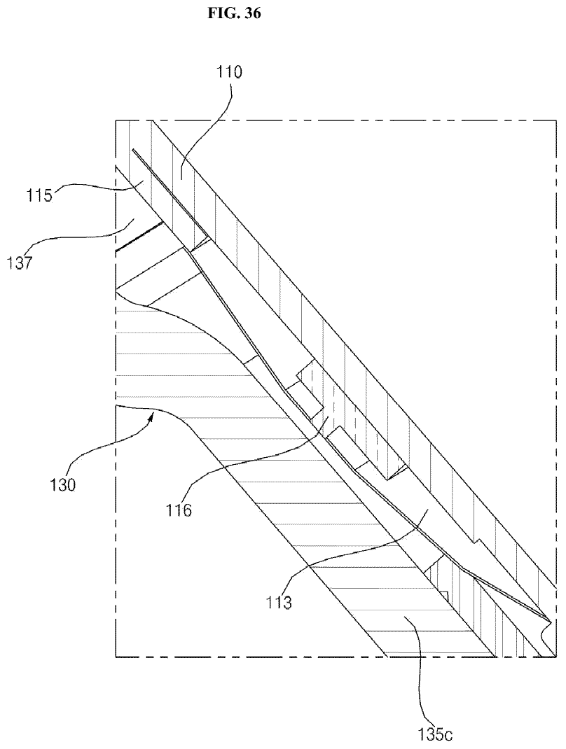

Referring to FIGS. 35 and 36, a driver IC 116 may be positioned at the rear surface of the display panel 110 while being adjacent to the lower side of the display panel 110. For example, the driver IC 116 may control the pixels of the display panel 110. The driver IC 116 may be electrically connected to the flexible cable (COF) 113. The driver IC 116 may face the outer part 135 of the material complexed panel 130. For example, the driver IC 116 may face the third outer part 135c of the material complexed panel 130.

When the flatness of the third outer part 135c of the material complexed panel 130 is not obtained, it may cause the driver IC 116 to contact the third outer part 135c. Consequently, the driver IC 116 may be short-circuited to the material complexed panel 130 or damaged by the material complexed panel 130. Therefore, obtaining the flatness of the outer part 135, 135c of the material complexed panel 130 may affect the lifespan of the display panel 110 including the driver IC 116.

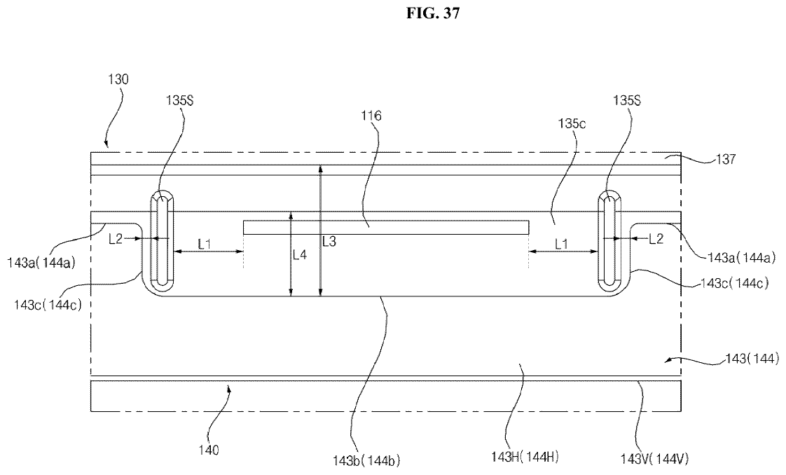

Referring to FIG. 37, a barrier line 135s may be positioned at the third outer part 135c. The barrier line 135s may be engraved in such a manner that the front skin 132 of the third outer part 135c and the core 131 of the material complexed panel 130 are pressed. The barrier line 135s may be referred to as a depressed line 135s, a depressed slit 135s, a barrier slit 135s, or an engraved line 135s.

The third part 143 or the fourth part 144 of the side frame 140 may include a first edge line (143a, 144a), a second edge line (143b, 144b), and a third edge line (143c, 144c). The first edge line (143a, 144a) may define an outermost edge of the horizontal portion (143H, 144H) of the third part 143 or the fourth part 144 of the side frame 140. The second edge line (143b, 144b) may be positioned between the first edge line (143a, 144a) and the vertical portion (143V, 144V) at the horizontal portion (143H, 144H) of the third part 143 or the fourth part 144 of the side frame 140 to thereby define an outer edge of the horizontal portion (143H, 144H). The third edge line (143c, 144c) may connect the first edge line (143a, 144a) and the second edge line (143b, 144b). The second edge line (143b, 144b) and the third edge line (143c, 144c) may allow the third outer part 135c of the material complexed panel 130 to be exposed forward.

A fourth distance L4 from the second edge line (143b, 144b) to a boundary of the third outer part 135c may be less than a third distance L3 from the second edge line (143b, 144b) to a boundary of the receiving part 137. A step surface (see FIG. 25) of the receiving part 137 and the third outer part 135c may be formed between the third distance L3 and the fourth distance L4.

The driver IC 116 may be positioned between the display panel 110 (see FIG. 35) and the third outer part 135c while facing the third outer part 135c. The driver IC 116 may extend parallel to the second edge line (143b, 144b). The driver IC 116 may have a length less than a length of the second edge line (143b, 144b). The driver IC 116 may be positioned closer to the boundary of the third outer part 135c than the second edge line (143b, 144b).

The barrier line 135s may be provided in plurality. The plurality of barrier lines 135s may be positioned adjacent to the third edge lines (143c, 144c), respectively. The barrier line 135s may have a length between the third distance L3 and the fourth distance L4. The barrier line 135s may be formed in the third outer part 135c. A portion of the barrier line 135s may be formed in a step surface (see FIG. 25) formed at a boundary between the third outer part 135c and the receiving part 137. A first distance L1 from an end of the driver IC 116 to the barrier line 135s may be greater than a second distance L2 from the barrier line 135s to the third edge line (143c, 144c).

Thus, it is possible to form the outer part 135c of the material complexed panel 130 to be flat and prevent a short-circuit and/or damage of the driver IC 116.

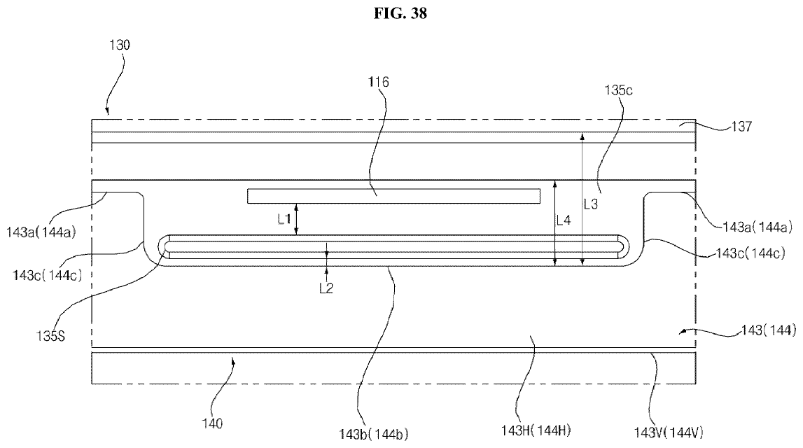

Referring to FIG. 38, a barrier line 135s may be positioned at the third outer part 135c. The barrier line 135s may be engraved in such a manner that the front skin 132 of the third outer part 135c and the core 131 of the material complexed panel 130 are pressed. The barrier line 135s may be referred to as a depressed line 135s, a depressed slit 135s, or a barrier slit 135s.

The third part 143 or the fourth part 144 of the side frame 140 may include a first edge line (143a, 144a), a second edge line (143b, 144b), and a third edge line (143c, 144c). The first edge line (143a, 144a) may define an outermost edge of the horizontal portion (143H, 144H) of the third part 143 or the fourth part 144 of the side frame 140. The second edge line (143b, 144b) may be positioned between the first edge line (143a, 144a) and the vertical portion (143V, 144V) at the horizontal portion (143H, 144H) of the third part 143 or the fourth part 144 of the side frame 140 to thereby define an outer edge of the horizontal portion (143H, 144H). The third edge line (143c, 144c) may connect the first edge line (143a, 144a) and the second edge line (143b, 144b). The second edge line (143b, 144b) and the third edge line (143c, 144c) may allow the third outer part 135c of the material complexed panel 130 to be exposed forward.

A fourth distance L4 from the second edge line (143b, 144b) to a boundary of the third outer part 135c may be less than a third distance L3 from the second edge line (143b, 144b) to a boundary of the receiving part 137. A step surface (see FIG. 25) of the receiving part 137 and the third outer part 135c may be formed between the third distance L3 and the fourth distance L4.

The driver IC 116 may be positioned between the display panel 110 (see FIG. 35) and the third outer part 135c while facing the third outer part 135c. The driver IC 116 may extend parallel to the second edge line (143b, 144b). The driver IC 116 may have a length less than a length of the second edge line (143b, 144b). The driver IC 116 may be positioned closer to the boundary of the third outer part 135c than the second edge line (143b, 144b).

The barrier line 135s may be elongated along the second edge line (143b, 144b) and/or a longitudinal direction of the driver IC 116. The barrier line 135s may have a length greater than the length of the driver IC 116 and less than the length of the second edge line (143b, 144b). The barrier line 135s may be parallel to the second edge line (143b, 144b) and/or the driver IC 116.

The barrier line 135s may be formed in the third outer pat 135c. A first distance L1 from the driver IC 116 to the barrier line 135s may be less than a second distance L2 from the barrier line 135s to the second edge line (143b, 144b).

Thus, it is possible to form the outer part 135c of the material complexed panel 130 to be flat and prevent a short-circuit and/or damage of the driver IC 116.

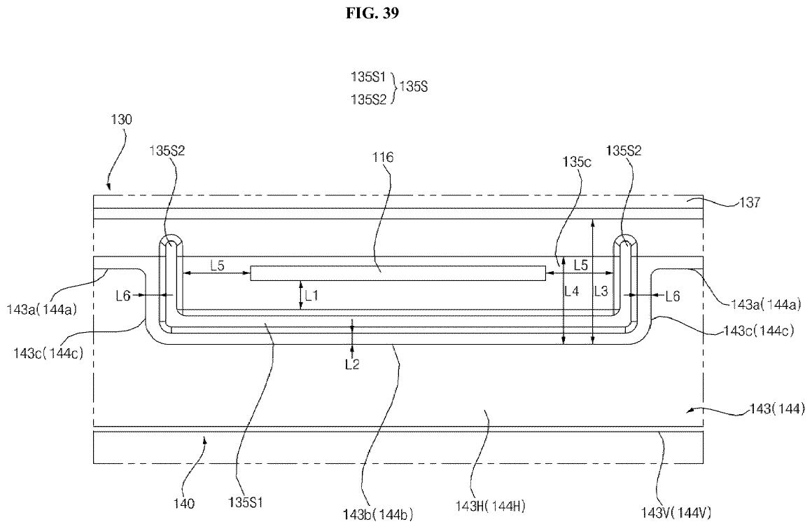

Referring to FIG. 39, a barrier line 135s may be positioned at the third outer part 135c. The barrier line 135s may be engraved in such a manner that the front skin 132 of the third outer part 135c and the core 131 of the material complexed panel 130 are pressed. The barrier line 135s may be referred to as a depressed line 135s, a depressed slit 135s, or a barrier slit 135s.

The third part 143 or the fourth part 144 of the side frame 140 may include a first edge line (143a, 144a), a second edge line (143b, 144b), and a third edge line (143c, 144c). The first edge line (143a, 144a) may define an outermost edge of the horizontal portion (143H, 144H) of the third part 143 or the fourth part 144 of the side frame 140. The second edge line (143b, 144b) may be positioned between the first edge line (143a, 144a) and the vertical portion (143V, 144V) at the horizontal portion (143H, 144H) of the third part 143 or the fourth part 144 of the side frame 140 to thereby define an outer edge of the horizontal portion (143H, 144H). The third edge line (143c, 144c) may connect the first edge line (143a, 144a) and the second edge line (143b, 144b). The second edge line (143b, 144b) and the third edge line (143c, 144c) may allow the third outer part 135c of the material complexed panel 130 to be exposed forward.

A fourth distance L4 from the second edge line (143b, 144b) to a boundary of the third outer part 135c may be less than a third distance L3 from the second edge line (143b, 144b) to a boundary of the receiving part 137. A step surface (see FIG. 25) of the receiving part 137 and the third outer part 135c may be formed between the third distance L3 and the fourth distance L4.

The driver IC 116 may be positioned between the display panel 110 (see FIG. 35) and the third outer part 135c while facing the third outer part 135c. The driver IC 116 may extend parallel to the second edge line (143b, 144b). The driver IC 116 may have a length less than a length of the second edge line (143b, 144b). The driver IC 116 may be positioned closer to the boundary of the third outer part 135c than the second edge line (143b, 144b).

The barrier line 135s may be provided in plurality. The plurality of barrier lines 135s may include a vertical barrier line 135s2 and a horizontal barrier line 135s1. A pair of vertical barrier lines 135s2 may be adjacent to or neighbor the third edge lines (143c, 144c), respectively. The vertical barrier line 135s2 may have a length between the third distance L3 and the fourth distance L4. The vertical barrier line 135s2 may be formed in the third outer part 135c. A portion of the vertical barrier line 135s2 may be formed in a step surface (see FIG. 25) formed at a boundary between the third outer part 135c and the receiving part 137. A fifth distance L5 from an end of the driver IC 116 to the vertical barrier line 135s2 may be greater than a sixth distance L6 from the vertical barrier line 135s2 to the third edge line (143c, 144c).

The horizontal barrier line 135s1 may be elongated along the second edge line (143b, 144b) and/or a longitudinal direction of the driver IC 116. The horizontal barrier line 135s1 may have a length greater than the length of the driver IC 116 and less than the length of the second edge line (143b, 144b). The horizontal barrier line 135s1 may be parallel to the second edge line (143b, 144b) and/or the driver IC 116. The horizontal barrier line 135s1 may be connected to the vertical barrier line 135s2.

The horizontal barrier line 135s1 may be formed in the third outer part 135c. A first distance L1 from the driver IC 116 to the horizontal barrier line 135s1 may be greater than a second distance L2 from the horizontal barrier line 135s1 to the second edge line (143b, 144b).

Thus, it is possible to form the outer part 135c of the material complexed panel 130 to be flat and prevent a short-circuit and/or damage of the driver IC 116.

Referring to FIGS. 1 to 39, a display device includes: a display panel 110; a material complexed panel 130 positioned at a rear of the display panel 110; and a side frame 140 positioned between the display panel 110 and the material complexed panel 130, fixed to the material complexed panel 130, and to which the display panel 110 is coupled. The material complexed panel 130 may include: a front skin 132 that defines a front surface thereof; a rear skin 133 that defines a rear surface thereof, the rear skin 133 facing the front skin 132; and a core 131 positioned between the front skin 132 and the rear skin 133, the core 131 including fibers. The material complexed panel 130 may include: a flat part 130P facing the display panel 110; an outer part 135 that defines a periphery of the flat part 130P, the outer part 135 having a front surface that defines a step descending from a front surface of the flat part 130P, which is formed by the front skin 132 and the core 131 being pressed; and a receiving part 137 formed on the outer part 135 along a longitudinal direction of one side of the display panel 110, the receiving part 137 having a front surface that defines a step descending from the front surface of the outer part 135. The outer part 135 may include a plurality of barrier lines 135s formed in a depressed manner on the front surface of the outer part 135 adjacent to the receiving part 137.

The display panel 110 may include a driver IC 116 disposed at a rear surface of the display panel 110 and electrically connected to the display panel 110. The driver IC 116 may be positioned between the display panel 110 and the outer part 135 of the material complexed panel 130.

The plurality of barrier lines 135s may be formed in the outer part 135c where the outer part 135c is opposite the flat part 130P with respect to the receiving part 137. The driver IC 116 may face the outer part 135c where the plurality of barrier lines 135s are formed.

The side frame 140 may include: a horizontal portion 143H, 144H positioned at the outer part 135c where the plurality of barrier lines 135s are formed; and a vertical portion 143V, 144V connected to the horizontal portion 143H, 144H, the vertical portion 143V, 144V covering a side surface of at least one of the display panel 110 or the material complexed panel 130. The horizontal portion 143H, 144H may include: a first edge line 143a, 144a adjacent to a boundary between the outer part 135c and the receiving part 137; a second edge line 143b, 144b positioned between the first edge line 143a, 144a and the vertical portion 143V, 144V; and a third edge line 143b, 144b connecting the first edge line 143a, 144a and the second edge line 143b, 144b. The outer part 135c facing the driver IC 116 may be exposed to an outside by the second edge line 143b, 144b and the third edge line 143c, 144c.

Each of the plurality of barrier lines 135s may be formed adjacent to the third edge line 143c, 144c.

The each of the plurality of barrier lines 135s may be configured as a plurality of barrier lines 135s extending in a direction intersecting the longitudinal direction of the one side of the display panel 110 and spaced apart from one another in the longitudinal direction of the one side of the display panel 110.

A first distance L1 from an end of the driver IC 116 to the each of the plurality of barrier lines 135s may be greater than a second distance L2 from the each of the plurality of barrier lines 135s to the third edge line 143H, 144H of the horizontal portion 143H, 144H of the side frame 140.

Each of the plurality of barrier lines 135s may be adjacent to the second edge line 143b, 144b, and may be elongated along the second edge line 143b, 144b.

A first distance L1 from the driver IC 116 to the each of the plurality of barrier lines 135s may be greater than a second distance L2 from the second edge line 143b, 144b of the horizontal portion 143H, 144H of the side frame 140 to the each of the plurality of barrier lines 135s.

The driver IC 116 may be elongated along the second edge line 143b, 144b of the side frame 140. The each of the plurality of barrier lines 135s may have a length greater than a length of the driver IC 116.

Each of the plurality of barrier lines 135s may include: a horizontal barrier line 135s1 extending along the second edge line 143b, 144b; and a vertical barrier line 135s2 extending along the third edge line 143c, 144c and connected to the horizontal barrier line 135s1.

The driver IC 116 may be elongated along the second edge line 143b, 144b of the side frame 140. The horizontal barrier line 135s1 may have a length greater than a length of the driver IC 116.

A first distance L1 from the driver IC 116 to the horizontal barrier line 135s1 may be greater than a second distance L2 from the second edge line 143b, 144b of the horizontal portion 143H, 144H of the side frame 140 to the horizontal barrier line 135s1.

A third distance L5 from an end of the driver IC 116 to the vertical barrier line 135s2 may be greater than a fourth distance L6 from the vertical barrier line 135s2 to the third edge line 143c, 144c of the horizontal portion 143H, 144H of the side frame 140.

The front skin 132 and the core 131 may be pressed so that each of the plurality of barrier lines 135s defines a slit descending from the front surface of the outer part 135.

Certain embodiments or other embodiments of the disclosure described above are not mutually exclusive or distinct from each other. Any or all elements of the embodiments of the disclosure described above may be combined or combined with each other in configuration or function.

For example, a configuration “A” described in one embodiment of the disclosure and the drawings, and a configuration “B” described in another embodiment of the disclosure and the drawings may be combined with each other. Namely, although the combination between the configurations is not directly described, the combination is possible except in the case where it is described that the combination is impossible.

The above detailed description is to be construed in all aspects as illustrative and not restrictive. The scope of the disclosure should be determined by reasonable interpretation of the appended claims, and all changes coming within the equivalency range of the disclosure are intended to be embraced in the scope of the disclosure.

What is claimed is:

1. A display device comprising:
a display panel;
a material complexed panel positioned at a rear of the display panel; and
a side frame positioned between the display panel and the material complexed panel, fixed to the material complexed panel, and to which the display panel is coupled,
wherein the material complexed panel comprises:
a front skin that defines a front surface of the material complexed panel;
a rear skin that defines a rear surface of the material complexed panel, the rear skin facing the front skin; and
a core positioned between the front skin and the rear skin, the core including fibers,
wherein the material complexed panel includes:
a flat part facing the display panel;
an outer part that defines a periphery of the flat part, the outer part having a front surface that defines a step descending from a front surface of the flat part, which is formed by the front skin and the core being pressed; and
a receiving part formed on the outer part along a longitudinal direction of one side of the display panel, the receiving part having a front surface that defines a step descending from the front surface of the outer part, and
wherein the outer part includes a plurality of barrier lines formed in a depressed manner on the front surface of the outer part adjacent to the receiving part.

2. The display device of claim 1, wherein the display panel includes a driver IC that is disposed at a rear surface of the display panel and electrically connected to the display panel, and
wherein the driver IC is positioned between the display panel and the outer part of the material complexed panel.

3. The display device of claim 2, wherein the plurality of barrier lines are formed in the outer part where the outer part is opposite the flat part with respect to the receiving part, and
wherein the driver IC faces the outer part where the plurality of barrier lines are formed.

4. The display device of claim 3, wherein the side frame includes:
a horizontal portion positioned at the outer part where the plurality of barrier lines are formed; and
a vertical portion connected to the horizontal portion, the vertical portion covering a side surface of at least one of the display panel or the material complexed panel,
wherein the horizontal portion includes:
a first edge line adjacent to a boundary between the outer part and the receiving part;
a second edge line positioned between the first edge line and the vertical portion; and
a third edge line connecting the first edge line and the second edge line, and
wherein the outer part facing the driver IC is exposed to an outside by the second edge line and the third edge line.

5. The display device of claim 4, wherein each of the plurality of barrier lines is formed adjacent to the third edge line.

6. The display device of claim 5, wherein the each of the plurality of barrier lines is configured as a plurality of barrier lines extending in a direction intersecting the longitudinal direction of the one side of the display panel and spaced apart from one another in the longitudinal direction of the one side of the display panel.

7. The display device of claim 5, wherein a first distance from an end of the driver IC to the each of the plurality of barrier lines is greater than a second distance from the each of the plurality of barrier lines to the third edge line of the horizontal portion of the side frame.

8. The display device of claim 4, wherein each of the plurality of barrier lines is adjacent to the second edge line and is elongated along the second edge line.

9. The display device of claim 8, wherein a first distance from the driver IC to the each of the plurality of barrier lines is greater than a second distance from the second edge line of the horizontal portion of the side frame to the each of the plurality of barrier lines.

10. The display device of claim 9, wherein the driver IC is elongated along the second edge line of the side frame, and
wherein the each of the plurality of barrier lines has a length greater than a length of the driver IC.

11. The display device of claim 4, wherein each of the plurality of barrier lines includes:
a horizontal barrier line extending along the second edge line; and
a vertical barrier line extending along the third edge line and connected to the horizontal barrier line.

12. The display device of claim 11, wherein the driver IC is elongated along the second edge line of the side frame, and
wherein the horizontal barrier line has a length greater than a length of the driver IC.

13. The display device of claim 12, wherein a first distance from the driver IC to the horizontal barrier line is greater than a second distance from the second edge line of the horizontal portion of the side frame to the horizontal barrier line.

14. The display device of claim 13, wherein a third distance from an end of the driver IC to the vertical barrier line is greater than a fourth distance from the vertical barrier line to the third edge line of the horizontal portion of the side frame.

15. The display device of claim 1, wherein the front skin and the core are pressed so that each of the plurality of barrier lines defines a slit descending from the front surface of the outer part.
